(19) United States
(12) Patent Application Publication
(10) Pub. No.: US 2024/0017368 A1
(43) Pub. Date: Jan. 18, 2024

(54) METHOD OF AND APPARATUS FOR GRINDING WAFER

(71) Applicant: DISCO CORPORATION, Tokyo (JP)

(72) Inventor: Yohei GOKITA, Munich (DE)

(21) Appl. No.: 18/351,090

(22) Filed: Jul. 12, 2023

(30) Foreign Application Priority Data
Jul. 14, 2022 (JP) 2022-113215

(51) Int. Cl. B24B 7/22

(52) U.S. Cl. CPC B24B 7/228

(57) ABSTRACT

A wafer is ground by switching between a self-sharpening-accelerated grinding step and a self-sharpening-decelerated grinding step on the basis of a load current value of a spindle motor, a loading value of grindstones, and/or the distance that the grindstones are moved. Therefore, compared to grinding the wafer only in the self-sharpening-accelerated grinding step, abrasive grains dislodged from the grindstones are reduced, and the amount of wear of the grindstones is restrained. In addition, compared to grinding the wafer only in the self-sharpening-decelerated grinding step, fluids supplied to the grindstones are saved, the time required to grind the wafer is shortened, and the processing quality of the wafer is increased. Consequently, undue wear on the grindstones is restrained while maintaining a desired level of quality of the ground surface of the wafer, resulting in a reduction in the frequency at which a grinding wheel including the grindstones is replaced.

### BACKGROUND OF THE INVENTION

### Field of the Invention

The present invention relates to a method of and an apparatus for grinding a wafer.

### Description of the Related Art

Grindstones for grinding hard wafers such as Sic wafers and GaN wafers include abrasive grains bound together by a vitrified bond and contain many pores for allowing abrasive grains to come off easily, as disclosed in Japanese patent Nos. 4769488 and 4734041. However, abrasive grains that have been dislodged from grindstones may cause damage to hard wafers that are being ground by the grindstones.

According to the technology disclosed in Japanese patent No. 4664693, when grindstones move out of contact with a hard wafer, the grindstones are doused in a large amount of water. The large amount of water supplied to the grindstones as they depart from the hard wafer forces the dislodged abrasive grains to move away from the hard wafer in water streams. The large amount of water applied to the grindstones is also effective to prevent abrasive grains from falling off the grindstones. On the other hand, when the amount of water supplied to grindstones is reduced while the grindstones are grinding a hard wafer, the dislodgement of abrasive grains from the grindstones is accelerated, causing new abrasive grains to emerge and grind the hard wafer.

### SUMMARY OF THE INVENTION

However, though grinding hard wafers with grindstones on grinding wheels while dislodging many abrasive grains from the grindstones increases the quality of the ground surfaces of the hard wafers, the grinding wheels have to be replaced frequently because the grindstones are worn down quickly.

If hard wafers to be ground by grindstones has surface irregularities, then the surface irregularities work to cause a lot of abrasive grains to drop off from the grindstones while the hard wafers are being ground by the grindstones. As a result, the grindstones suffer undue wear, and hence the grinding wheels with the excessively worn grindstones have to be replaced at frequent intervals.

It is therefore an object of the present invention to provide a method of and an apparatus for grinding a wafer so as to minimize abrasive grains dropping off from grindstones and hence reduce undue wear on the grindstones while at the same time maintaining a desired level of the processing quality of the ground surface of the wafer.

In accordance with a first aspect of the present invention, there is provided a method of grinding a wafer with contact surfaces of grindstones that are rotated, including a self-sharpening-accelerated grinding step of supplying a first fluid for accelerating self-sharpening of the contact surfaces of the grindstones to the wafer and the grindstones and grinding the wafer with the grindstones, and a self-sharpening-decelerated grinding step of supplying a second fluid for decelerating self-sharpening of the contact surfaces of the grindstones to the wafer and the grindstones and grinding the wafer with the grindstones, in which, in the self-sharpening-accelerated grinding step when a load current value of a spindle motor that rotates the grindstones while the grindstones are grinding the wafer has reached a preset first current threshold value or a predetermined first period of time has elapsed after the load current value of the spindle motor reached the preset first current threshold value, or when a loading value for pressing the grindstones against the wafer has reached a preset first loading threshold value or a predetermined second period of time has elapsed after the loading value reached the preset first loading threshold value, or when the contact surfaces of the grindstones have further been moved in a direction toward the wafer by a predetermined distance after having contacted the wafer in the self-sharpening-accelerated grinding step, the self-sharpening-accelerated grinding step transitions to the self-sharpening-decelerated grinding step.

In accordance with a second aspect of the present invention, there is provided a method of grinding a wafer with contact surfaces of grindstones that are rotated, including a self-sharpening-accelerated grinding step of supplying a first fluid for accelerating self-sharpening of the contact surfaces of the grindstones to the wafer and the grindstones and grinding the wafer with the grindstones, and a self-sharpening-decelerated grinding step of supplying a second fluid for decelerating self-sharpening of the contact surfaces of the grindstones to the wafer and the grindstones and grinding the wafer with the grindstones, in which, in the self-sharpening-accelerated grinding step when a load current value of a spindle motor that rotates the grindstones while the grindstones are grinding the wafer has reached a preset first current threshold value or a predetermined first period of time has elapsed after the load current value of the spindle motor reached the preset first current threshold value, and when a loading value for pressing the grindstones against the wafer has reached a preset first loading threshold value or a predetermined second period of time has elapsed after the loading value reached the preset first loading threshold value, the self-sharpening-accelerated grinding step transitions to the self-sharpening-decelerated grinding step.

In accordance with a third aspect of the present invention, there is provided a method of grinding a wafer with contact surfaces of grindstones that are rotated, including a self-sharpening-decelerated grinding step of supplying a second fluid for decelerating self-sharpening of the contact surfaces of the grindstones to the wafer and the grindstones and grinding the wafer with the grindstones, and a self-sharpening-accelerated grinding step of supplying a first fluid for accelerating self-sharpening of the contact surfaces of the grindstones to the wafer and the grindstones and grinding the wafer with the grindstones, in which, in the self-sharpening-decelerated grinding step when a load current value of a spindle motor that rotates the grindstones while the grindstones are grinding the wafer has reached a preset second current threshold value or a predetermined first period of time has elapsed after the load current value of the spindle motor reached the preset second current threshold value, or when a loading value for pressing the grindstones against the wafer has reached a preset second loading threshold value or a predetermined second period of time has elapsed after the loading value reached the preset second loading threshold value, or when the contact surfaces of the grindstones have further been moved in a direction toward the wafer by a predetermined distance after having contacted the wafer in the self-sharpening-decelerated grinding step, the self-sharpening-decelerated grinding step transitions to the self-sharpening-accelerated grinding step.

In accordance with a fourth aspect of the present invention, there is provided a method of grinding a wafer with contact surfaces of grindstones that are rotated, including a self-sharpening-decelerated grinding step of supplying a second fluid for decelerating self-sharpening of the contact surfaces of the grindstones to the wafer the grindstones and grinding the wafer with the grindstones, and a self-sharpening-accelerated grinding step of supplying a first fluid for accelerating self-sharpening of the contact surfaces of the grindstones to the wafer and the grindstones and grinding the wafer with the grindstones, in which, in the self-sharpening-decelerated grinding step when a load current value of a spindle motor that rotates the grindstones while the grindstones are grinding the wafer has reached a preset second current threshold value or a predetermined first period of time has elapsed after the load current value of the spindle motor reached the preset second current threshold value, and when a loading value for pressing the grindstones against the wafer has reached a preset second loading threshold value or a predetermined second period of time has elapsed after the loading value reached the preset second loading threshold value, the self-sharpening-decelerated grinding step transitions to the self-sharpening-accelerated grinding step.

In accordance with a fifth aspect of the present invention, there is provided a method of grinding a wafer with contact surfaces of grindstones that are rotated, including a self-sharpening-accelerated grinding step of supplying a first fluid for accelerating self-sharpening of the contact surfaces of the grindstones to the wafer and the grindstones and grinding the wafer with the grindstones while measuring the thickness of the wafer with a thickness measuring unit, and a self-sharpening-decelerated grinding step of supplying a second fluid for decelerating self-sharpening of the contact surfaces of the grindstones to the wafer and the grindstones and grinding the wafer to a preset thickness with the grindstones, in which, when the thickness of the wafer measured by the thickness measuring unit has reached a preset first thickness threshold value, the self-sharpening-accelerated grinding step transitions to the self-sharpening-decelerated grinding step.

In accordance with a sixth aspect of the present invention, there is provided a method of grinding a wafer with contact surfaces of grindstones that are rotated, including a self-sharpening-accelerated grinding step of supplying a first fluid for accelerating self-sharpening of the contact surfaces of the grindstones to the wafer and the grindstones and grinding the wafer with the grindstones until the contact surfaces of the grindstones have further been moved in a direction toward the wafer by a predetermined distance after having contacted the wafer, a thickness measuring step of measuring the thickness of the wafer ground in the self-sharpening-accelerated grinding step, a self-sharpening-decelerated grinding step of supplying a second fluid for decelerating self-sharpening of the contact surfaces of the grindstones to the wafer and the grindstones and grinding the wafer to a preset thickness with the grindstones, and a regrinding step of, when the thickness measured in the thickness measuring step has not reached a preset first thickness threshold value, supplying the first fluid to the wafer and the grindstones and grinding the wafer with the grindstones until the contact surfaces of the grindstones have further been moved in the direction toward the wafer by a distance represented by the difference between the thickness measured in the thickness measuring step and the first thickness threshold value, in which, when the thickness measured by the thickness measuring unit has reached the preset first thickness threshold value, the self-sharpening-accelerated grinding step transitions to the self-sharpening-decelerated grinding step.

In accordance with a seventh aspect of the present invention, there is provided a method of grinding a wafer with contact surfaces of grindstones that are rotated, including a self-sharpening-decelerated grinding step of supplying a second fluid for decelerating self-sharpening of the contact surfaces of the grindstones to the wafer and the grindstones and grinding the wafer with the grindstones while measuring the thickness of the wafer with a thickness measuring unit, a thickness measuring step of measuring a thickness of the wafer ground in the self-sharpening-decelerated grinding step, and a self-sharpening-accelerated grinding step of supplying a first fluid for accelerating self-sharpening of the contact surfaces of the grindstones to the wafer and the grindstones and grinding the wafer to a preset thickness with the grindstones, in which, when the thickness of the wafer measured by the thickness measuring unit has reached a preset second thickness threshold value, the self-sharpening-decelerated grinding step transitions to the self-sharpening-accelerated grinding step.

In accordance with an eighth aspect of the present invention, there is provided a method of grinding a wafer with contact surfaces of grindstones that are rotated, including a self-sharpening-decelerated grinding step of supplying a second fluid for decelerating self-sharpening of the contact surfaces of the grindstones to the wafer and the grindstones and grinding the wafer with the grindstones until the contact surfaces of the grindstones have further been moved in a direction toward the wafer by a predetermined distance after having contacted the wafer, a thickness measuring step of measuring the thickness of the wafer ground in the self-sharpening-decelerated grinding step, a self-sharpening-accelerated grinding step of supplying a first fluid for accelerating self-sharpening of the contact surfaces of the grindstones to the wafer and the grindstones and grinding the wafer to a preset thickness with the grindstones, and a regrinding step of, when the thickness measured in the thickness measuring step has not reached a preset second thickness threshold value, supplying the second fluid to the wafer and the grindstones and grinding the wafer with the grindstones until the contact surfaces of the grindstones have further been moved in the direction toward the wafer by a distance represented by the difference between the thickness measured in the thickness measuring step and the second thickness threshold value, in which, when the thickness measured by the thickness measuring unit has reached the preset second thickness threshold value, the self-sharpening-decelerated grinding step transitions to the self-sharpening-accelerated grinding step.

Preferably, in the method of grinding a wafer according to the first aspect of the invention, the self-sharpening-accelerated grinding step transitions to the self-sharpening-decelerated grinding step when the load current value of the spindle motor that rotates the grindstones while the grindstones are grinding the wafer has become smaller than the preset first current threshold value or a third predetermined period of time has elapsed after the load current value of the spindle motor became smaller than the preset first current threshold value, or when the loading value for pressing the grindstones against the wafer has become smaller than the preset first loading threshold value or a fourth predetermined period of time has elapsed after the loading value became smaller than the preset first loading threshold value, or when the contact surfaces of the grindstones have further been moved in the direction toward the wafer by the predetermined distance after having contacted the wafer in the self-sharpening-accelerated grinding step.

Preferably, in the method of grinding a wafer according to the second aspect of the invention, the self-sharpening-accelerated grinding step transitions to the self-sharpening-decelerated grinding step when the load current value of the spindle motor that rotates the grindstones while the grindstones are grinding the wafer has become smaller than the preset first current threshold value or a third predetermined period of time has elapsed after the load current value of the spindle motor became smaller than the preset first current threshold value, and when the loading value for pressing the grindstones against the wafer has become smaller than the preset first loading threshold value or a fourth predetermined period of time has elapsed after the loading value became smaller than the preset first loading threshold value.

Preferably, in the method of grinding a wafer according to the third aspect of the invention, the self-sharpening-decelerated grinding step transitions to the self-sharpening-accelerated grinding step when the load current value of the spindle motor that rotates the grindstones while the grindstones are grinding the wafer has become larger than the preset second current threshold value or a third predetermined period of time has elapsed after the load current value of the spindle motor became larger than the preset second current threshold value, or when the loading value for pressing the grindstones against the wafer has become larger than the preset second loading threshold value or a fourth predetermined period of time has elapsed after the loading value became larger than the preset second loading threshold value, or when the contact surfaces of the grindstones have further been moved in the direction toward the wafer by the predetermined distance after having contacted the wafer in the self-sharpening-decelerated grinding step.

Preferably, in the method of grinding a wafer according to the fourth aspect of the invention, the self-sharpening-decelerated grinding step transitions to the self-sharpening-accelerated grinding step when the load current value of the spindle motor that rotates the grindstones while the grindstones are grinding the wafer has become larger than the preset second current threshold value or a third predetermined period of time has elapsed after the load current value of the spindle motor became larger than the preset second current threshold value, and when the loading value for pressing the grindstones against the wafer has become larger than the preset second loading threshold value or a fourth predetermined period of time has elapsed after the loading value became larger than the preset second loading threshold value.

Preferably, in the methods of grinding a wafer according to the first through eighth aspects of the invention, the first fluid includes a liquid supplied at a preset first flow rate, and the second fluid includes a liquid supplied at a second flow rate higher than the preset first flow rate.

Alternatively, the first fluid includes air supplied at a preset third flow rate, and the second fluid includes a liquid supplied at a preset fourth flow rate.

Alternatively, the first fluid or the second fluid includes a mixture of a liquid and air. Alternatively, the first fluid and the second fluid are a mixture of a liquid and air, and the first fluid is supplied at a total flow rate as a fifth flow rate, and the second fluid is supplied at a total flow rate as a sixth flow rate higher than the fifth flow rate.

In accordance with a ninth aspect of the present invention, there is provided an apparatus for grinding a wafer with contact surfaces of grindstones that are rotated, including a chuck table for holding the wafer thereon, a grinding mechanism for grinding the wafer on the chuck table, the grinding mechanism having the grindstones and an electric motor for rotating the grindstones that are arranged in an annular array about a central axis of the annular array, a moving mechanism for moving the chuck table and the grinding mechanism relatively toward and away from each other, a fluid supply mechanism for selectively supplying a first fluid and a second fluid at adjustable flow rates to the wafer and the grindstones, a load current value measuring unit for measuring a load current value of the electric motor when the electric motor rotates the grindstones, and a controller, in which the controller includes a first controller for carrying out a control process to control the fluid supply mechanism to supply the first fluid and move the chuck table and the grindstones relatively in directions toward each other at a predetermined feed speed, thereby grinding the wafer with the grindstones, and a second controller for carrying out a control process to control the fluid supply mechanism to supply the second fluid and move the chuck table and the grindstones relatively in directions toward each other at a predetermined feed speed, thereby grinding the wafer with the grindstones, the control process carried out by the first controller transitions to the control process carried out by the second controller when the load current value has reached a preset first current threshold value or a predetermined first period of time has elapsed after the load current value reached the preset first current threshold value, and the control process carried out by the second controller transitions to the control process carried out by the first controller when the load current value has reached a preset second current threshold value or a predetermined second period of time has elapsed after the load current value reached the preset second current threshold value.

Preferably, the apparatus for grinding a wafer according to the ninth aspect of the invention further includes a loading value measuring unit for measuring a loading value applied relatively to the grindstones and the wafer, in which the control process carried out by the first controller transitions to the control process carried out by the second controller when the loading value has reached a preset first loading threshold value or a third predetermined period of time has elapsed after the loading value has reached the preset first loading threshold value, and the control process carried out by the second controller transitions to the control process carried out by the first controller when the loading value has reached a preset second loading threshold value or a fourth predetermined period of time has elapsed after the loading value has reached the preset second loading threshold value.

In accordance with a tenth aspect of the present invention, there is provided an apparatus for grinding a wafer with contact surfaces of grindstones that are rotated, including a chuck table for holding the wafer thereon, a grinding mechanism for grinding the wafer on the chuck table, the grinding mechanism having the grindstones and an electric motor for rotating the grindstones that are arranged in an annular array about a central axis of the annular array, a moving mechanism for moving the chuck table and the grinding mechanism relatively toward and away from each other, a fluid supply mechanism for selectively supplying a first fluid and a second fluid at adjustable flow rates to the wafer and the grindstones, and a controller, in which the controller includes a first controller for carrying out a control process to control the fluid supply mechanism to supply the first fluid and move the chuck table and the grindstones relatively in directions toward each other at a predetermined first feed speed, thereby grinding the wafer with the grindstones, and a second controller for carrying out a control process to control the fluid supply mechanism to supply the second fluid and move the chuck table and the grindstones relatively in directions toward each other at a predetermined second feed speed, thereby grinding the wafer with the grindstones, and the control process carried out by the first controller transitions to the control process carried out by the second controller or the control process carried out by the second controller transitions to the control process carried out by the first controller when the contact surfaces of the grindstones have further been moved in a direction toward the wafer by a predetermined distance after having contacted the wafer.

In accordance with an eleventh aspect of the present invention, there is provided an apparatus for grinding a wafer with contact surfaces of grindstones that are rotated, including a chuck table for holding the wafer thereon, a grinding mechanism for grinding the wafer on the chuck table, the grinding mechanism having the grindstones and an electric motor for rotating the grindstones that are arranged in an annular array about a central axis of the annular array, a moving mechanism for moving the chuck table and the grinding mechanism relatively toward and away from each other, a fluid supply mechanism for selectively supplying a first fluid and a second fluid at adjustable flow rates to the wafer and the grindstones, a load current value measuring unit for measuring a load current value of the electric motor when the electric motor rotates the grindstones, a loading value measuring unit for measuring a loading value applied relatively to the grindstones and the wafer, and a controller, in which the controller includes a first controller for carrying out a control process to control the fluid supply mechanism to supply the first fluid and move the chuck table and the grindstones relatively in directions toward each other at a predetermined first feed speed, thereby grinding the wafer with the grindstones, and a second controller for carrying out a control process to control the fluid supply mechanism to supply the second fluid and move the chuck table and the grindstones relatively in directions toward each other at a predetermined second feed speed, thereby grinding the wafer with the grindstones, the control process carried out by the first controller transitions to the control process carried out by the second controller when the load current value has reached a preset first current threshold value or a predetermined first period of time has elapsed after the load current value reached the preset first current threshold value, and when the loading value has reached a preset first loading threshold value or a predetermined second period of time has elapsed after the loading value reached the preset first loading threshold value, and the control process carried out by the second controller transitions to the control process carried out by the first controller when the load current value has reached a preset second current threshold value or a predetermined third period of time has elapsed after the load current value reached the preset second current threshold value, and when the loading value has reached a preset second loading threshold value or a predetermined fourth period of time has elapsed after the loading value reached the preset second loading threshold value.

Preferably, the apparatus for grinding a wafer according to the ninth aspect of the invention or the apparatus for grinding a wafer according to the eleventh aspect of the invention further includes a thickness measuring unit for measuring the thickness of the wafer held on the chuck table, in which the control process carried out by the first controller also transitions to the control process carried out by the second controller when the thickness of the wafer measured by the thickness measuring unit has reached a preset first thickness threshold value, and the control process carried out by the second controller also transitions to the control process carried out by the first controller when the thickness of the wafer measured by the thickness measuring unit has reached a preset second thickness threshold value.

According to the present invention, a wafer is ground by switching between a self-sharpening-accelerated grinding step and a self-sharpening-decelerated grinding step on the basis of a load current value of a spindle motor, a loading value of grindstones, and/or the distance that the grindstones are moved. Therefore, compared to grinding the wafer only in the self-sharpening-accelerated grinding step, abrasive grains dislodged from the grindstones are reduced, and the amount of wear of the grindstones is restrained. In addition, compared to grinding the wafer only in the self-sharpening-decelerated grinding step, fluids supplied to the grindstones are saved, the time required to grind the wafer is shortened, and the processing quality of the wafer is increased. Consequently, according to the present invention, undue wear on the grindstones is restrained while at the same time maintaining a desired level of the processing quality of the ground surface of the wafer, resulting in a reduction in the frequency at which a grinding wheel including the grindstones is replaced.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating a structural example of a grinding apparatus according to an embodiment of the present invention;

FIG. 2 is a graph illustrating an example of time-dependent changes in the height of grindstones;

FIG. 3 is a graph illustrating an example of time-dependent changes in load current values and loading values;

FIG. 4 is a graph illustrating another example of time-dependent changes in load current values and loading values;

FIG. 5 is a graph illustrating still another example of time-dependent changes in load current values and loading values; and

FIGS. 6A and 6B are schematic views illustrating a structural example of an edge grinding apparatus according to another embodiment of the present invention.

### DETAILED DESCRIPTION OF THE PREFERRED EMBODIMENTS

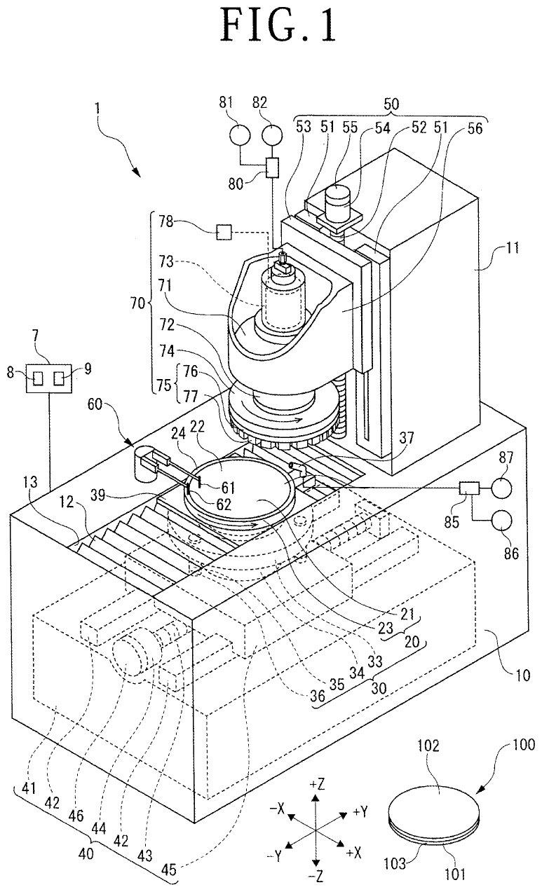

As illustrated in FIG. 1, a grinding apparatus 1 according to an embodiment of the present invention represents an example of an apparatus for grinding a wafer 100 with contact surfaces of grindstones 77 that are arranged in an annular array. In FIG. 1, the grinding apparatus 1 is illustrated in reference to a three-dimensional coordinate system having X-, Y-, and Z-axes indicated by the respective pairs of arrows +X and −X, +Y and −Y, and +Z and −Z. X-axis directions, i.e., leftward and rightward directions, that extend horizontally parallel to the X-axis, and Y-axis directions, i.e., forward and rearward directions, that extend horizontally parallel to the Y-axis are perpendicular to each other on a horizontal plane. Z-axis directions, i.e., upward and downward directions, that extend vertically parallel to the Z-axis are perpendicular to the X-axis directions and the Y-axis directions. The X-axis directions include +X direction and −X direction that are opposite each other, the Y-axis directions include +Y direction and −Y direction that are opposite each other, and the Z-axis directions include +Z direction and −Z direction that are opposite each other.

The wafer 100 is a circular semiconductor wafer, for example, and has a face side 101 and a reverse side 102 that are opposite each other. A plurality of devices, not illustrated, are constructed on the face side 101 of the wafer 100 that face upwardly in FIG. 1. The devices are protected by a protective sheet 103 affixed to the face side 101 of the wafer 100. The reverse side 102 of the wafer 100 will be a surface to be processed by a grinding process performed on the grinding apparatus 1.

The wafer 100 may be modified as follows. The wafer 100 may be free of the protective sheet 103 that would be affixed to the face side 101 thereof. Both the reverse side 102 and face side 101 of the wafer 100 may be ground by the grinding apparatus 1. The wafer 100 may be a wafer blank free of a plurality of devices on its face side, and the wafer blank may have both face and reverse sides ground by the grinding apparatus 1.

The grinding apparatus 1 includes a base block 10 with an opening 13 defined in an upper surface thereof. The opening 13 houses a wafer holding mechanism 30 disposed therein. The wafer holding mechanism 30 includes a circular chuck table 20 for holding the wafer 100 thereon, a support member 33 supporting the chuck table 20 thereon, a chuck table motor 34 for rotating the chuck table 20 about its vertical central axis, and a support post 35 for adjusting the tilt of the chuck table 20.

The chuck table 20 includes a circular porous member 21 and a frame 23 housing the porous member 21 therein such that the porous member 21 has an exposed upper surface. The exposed upper surface of the porous member 21 functions as a holding surface 22 for holding the wafer 100 under suction thereon. The holding surface 22 is fluidly connected to a suction source, not illustrated, that applies a suction force to the holding surface 22 to enable the holding surface 22 to hold the wafer 100 under suction thereon. Therefore, the chuck table 20 holds the wafer 100 under suction on the holding surface 22. The frame 23 has an annular upper frame surface 24 that lies flush with the holding surface 22.

When energized, the chuck table motor 34 rotates the chuck table 20 about its vertical central axis aligned with the center of the holding surface 22. The chuck table 20 with the wafer 100 held under suction on the holding surface 22 can thus be rotated by the chuck table motor 34 about the vertical central axis aligned with the center of the holding surface 22.

The support post 35 for adjusting the tilt of the chuck table 20 is combined with a loading value measuring unit 36. The loading value measuring unit 36 measures the vertical loading value of a loading force applied to the grindstones 77 relatively to the wafer 100. The vertical loading value represents a vertical loading force that is applied to press the grindstones 77 vertically downwardly against the wafer 100 while the grindstones 77 are grinding the wafer 100. The loading value measuring unit 36 measures the vertical loading value of the vertical loading force applied from the grindstones 77 of a grinding mechanism 70 to the wafer 100 held under suction on the holding surface 22 of the chuck table 20. The loading value measuring unit 36 thus measures the vertical loading value of the loading force applied vertically to respective lower surfaces, i.e., the contact surfaces, of grindstones 77. The vertical loading value represents an example of the vertical loading value representing the vertical loading force that presses the grindstones 77 against the wafer 100 while the grindstones 77 are grinding the wafer 100. The loading value measuring unit 36 may be incorporated in the grinding mechanism 70 rather than the support post 35.

The chuck table 20 has its periphery covered with a cover plate 39 that is movable along the Y-axis together with the chuck table 20. Bellows-shaped covers 12 that can be extended and contracted along the Y-axis are coupled to respective sides of the cover plate 39 that face in the respective +Y and −Y directions. The wafer holding mechanism 30 is disposed above a Y-axis moving mechanism 40 housed in the base block 10.

The Y-axis moving mechanism 40 moves the chuck table 20 and the grinding mechanism 70 relatively to each other along the Y-axis that extends parallel to the holding surface 22. According to the present embodiment, the Y-axis moving mechanism 40 is arranged to move the wafer holding mechanism 30 that includes the chuck table 20 along the Y-axis with respect to the grinding mechanism 70 that remains fixed against movement along the Y-axis.

The Y-axis moving mechanism 40 includes a pair of Y-axis guide rails 42 extending parallel to the Y-axis, a Y-axis movable table 45 slidable on and along the Y-axis guide rails 42, a Y-axis ball screw 43 disposed between and extending parallel to the Y-axis guide rails 42, a Y-axis electric motor 44 connected to the Y-axis ball screw 43, a Y-axis encoder 46 for detecting the angle of rotation of the Y-axis electric motor 44, and a holding base 41 that supports the Y-axis guide rails 42, the Y-axis movable table 45, the Y-axis ball screw 43, the Y-axis electric motor 44, and the Y-axis encoder 46 thereon.

The Y-axis movable table 45 is disposed on the Y-axis guide rails 42 for sliding movement along the Y-axis guide rails 42. The Y-axis movable table 45 has a lower surface to which a nut, not illustrated, is fixed. The Y-axis ball screw 43 is operatively threaded through the nut. The Y-axis electric motor 44 is connected to an end of the Y-axis ball screw 43.

When the Y-axis electric motor 44 is energized, it rotates the Y-axis ball screw 43 about its horizontal central axis, causing the nut to move itself and the Y-axis movable table 45 in the +Y or −Y direction along the Y-axis. The support member 33 of the wafer holding mechanism 30 is mounted on the Y-axis movable table 45 by the support post 35. Therefore, as the Y-axis movable table 45 moves along the Y-axis, the wafer holding mechanism 30 including the chuck table 20 also moves along the Y-axis in the same direction as the Y-axis movable table 45.

According to the present embodiment, the Y-axis moving mechanism 40 moves the wafer holding mechanism 30 along the Y-axis between a wafer placing area, where the wafer 100 is placed on the holding surface 22, spaced away from the grinding mechanism 70 in the −Y direction and a wafer grinding area, where the wafer 100 on the holding surface 22 is ground by the grinding mechanism 70, disposed below the grinding mechanism 70 and spaced away from the wafer placing area in the +Y direction.

When the Y-axis electric motor 44 rotates the Y-axis ball screw 43 about its central axis, the Y-axis encoder 46 is also rotated by the Y-axis electric motor 44 to recognize the angle of rotation of the Y-axis electric motor 44. On the basis of the recognized angle of rotation, the Y-axis encoder 46 detects the position along the Y-axis of the chuck table 20 of the wafer holding mechanism 30 that is being moved along the Y-axis.

As illustrated in FIG. 1, the grinding apparatus 1 also includes an upstanding column 11 mounted on the base block 10 behind the wafer holding mechanism 30 in the +Y direction. The grinding mechanism 70 for grinding the wafer 100 on the chuck table 20 and a Z-axis moving mechanism 50 for vertically moving the grinding mechanism 70 are mounted on a front surface of the column 11 that faces in the −Y direction.

The Z-axis moving mechanism 50 represents an example of a moving mechanism for moving the chuck table 20 and the grinding mechanism 70 in directions relatively toward and away from each other. The Z-axis moving mechanism 50 moves the chuck table 20 and the grinding mechanism 70 relatively to each other along the Z-axis, i.e., in grinding feed directions, perpendicular to the holding surface 22 in the wafer grinding area. According to the present embodiment, the Z-axis moving mechanism 50 is arranged to move the grindstones 77 of the grinding mechanism 70 along the Z-axis with respect to the chuck table 20 in the wafer grinding area.

The Z-axis moving mechanism 50 includes a pair of Z-axis guide rails 51 attached to the front surface of the column 11 and extending parallel to the Z-axis, a Z-axis movable table 53 slidable on and along the Z-axis guide rails 51, a Z-axis ball screw 52 disposed between and extending parallel to the Z-axis guide rails 51, a Z-axis electric motor 54 connected to the Z-axis ball screw 52, a Z-axis encoder 55 for detecting the angle of rotation of the Z-axis electric motor 54, and a holder 56 mounted on the Z-axis movable table 53. The holder 56 holds the grinding mechanism 70 thereon.

The Z-axis movable table 53 is disposed on the Z-axis guide rails 51 for sliding movement along the Z-axis guide rails 51. The Z-axis movable table 53 has a rear surface to which a nut, not illustrated, is fixed. The Z-axis ball screw 52 is operatively threaded through the nut. The Z-axis electric motor 54 is connected to an end of the Z-axis ball screw 52.

When the Z-axis electric motor 54 is energized, it rotates the Z-axis ball screw 52 about its vertical central axis, causing the nut to move itself and the Z-axis movable table 53 in the +Z or −Z direction along the Z-axis. As the Z-axis movable table 53 moves along the Z-axis, the holder 56 that is mounted on the Z-axis movable table 53 and the grinding mechanism 70 that is supported on the holder 56 also move along the Z-axis in the same direction as the Z-axis movable table 53.

When the Z-axis electric motor 54 rotates the Y-axis ball screw 52 about its central axis, the Z-axis encoder 55 is also rotated by the Z-axis electric motor 54 to recognize the angle of rotation of the Z-axis electric motor 54. On the basis of the recognized angle of rotation, the Z-axis encoder 55 detects the position, i.e., the height, along the Z-axis of the grindstones 77 of the grinding mechanism 70 that is being moved along the Z-axis.

The grinding mechanism 70 has a spindle motor 73 for rotating the annular array of the grindstones 77 about its central axis to grind the wafer 100 on the chuck table 20. The grinding mechanism 70 includes a spindle housing 71 fixed to the holder 56, a spindle 72 rotatably held by the spindle housing 71, the spindle motor 73 that rotates the spindle 72, a wheel mount 74 joined to a lower end of the spindle 72, and a grinding wheel 75 supported on the wheel mount 74.

The spindle housing 71 is held by the holder 56 and extends vertically along the Z-axis. The spindle 72 extends vertically along the Z-axis perpendicularly to the holding surface 22 of the chuck table 20 and is rotatably supported by the spindle housing 71.

The spindle motor 73 is coupled to an upper end of the spindle 72. The spindle motor 73, when energized, rotates the spindle 72 about its vertical central axis along the Z-axis.

The wheel mount 74 is shaped as a circular plate and fixed to the lower end of the spindle 72. The wheel mount 74 supports the grinding wheel 75 on its lower surface.

The grinding wheel 75 has an outside diameter that is substantially the same as the outside diameter of the wheel mount 74. The grinding wheel 75 includes an annular base 76 made of a metal material. The annular array of the grindstones 77 is fixed to a lower surface of the grinding wheel 75, i.e., the annular base 76, and extends fully circumferentially along the lower surface of the annular base 76. While the grindstones 77 are being held in abrasive contact with the wafer 100 with their annular array being kept on the center of the wafer 100, the grindstones 77 are rotated about the center of their annular array by the spindle 72 rotated by the spindle motor 73, grinding the reverse side 102 of the wafer 100 held on the chuck table 20.

According to the present embodiment, the grindstones 77 include abrasive grains bound together by a vitrified bond and contain many pores for allowing abrasive grains to come off easily. The grindstones 77 include grindstones that tend to be self-sharpened when the amount of a fluid such as water supplied to the wafer 100 and the grindstones 77 as it is ground is small. The grindstones 77 may include abrasive grains bound together by a resin bond. According to the present invention, the abrasive grains of the grindstones 77 may be bound together by other binders than the vitrified bond and the resin bond.

The grinding mechanism 70 has a load current value measuring unit 78. The load current value measuring unit 78 measures load current values of the spindle motor 73 that rotates the grindstones 77.

A first supply mechanism 80 is fluidly connected to an upper portion of the grinding mechanism 70. The first supply mechanism 80 represents an example of a fluid supply mechanism that selectively supplies a first fluid and a second fluid at adjustable flow rates to the wafer 100 and the grindstones 77. The first supply mechanism 80 is also fluidly connected to a first liquid source 81 and a first air source 82. The first supply mechanism 80 supplies a fluid from the first liquid source 81 or the first air source 82 through a fluid channel, not illustrated, in the spindle 72 to the grindstones 77 and the reverse side 102 of the wafer 100.

A fluid nozzle 37 is mounted on a portion of the cover plate 39 that extends away from the chuck table 20 in the +Y direction. A second supply mechanism 85 is fluidly connected to the fluid nozzle 37.

The second supply mechanism 85 represents an example of a fluid supply mechanism that selectively supplies a first fluid and a second fluid at adjustable flow rates to the wafer 100 and the grindstones 77. The second supply mechanism 85 is also fluidly connected to a second liquid source 86 and a second air source 87. The second supply mechanism 85 supplies a fluid from the second liquid source 86 or the second air source 87 through the fluid nozzle 37 to the grindstones 77 and the reverse side 102 of the wafer 100.

As described above, the first supply mechanism 80 and the second supply mechanism 85 supply fluids at adjustable flow rates to the wafer 100 and the grindstones 77. According to the present embodiment, the first supply mechanism 80 and the second supply mechanism 85 are able to supply two fluids including a liquid and air or a mixture of a liquid and air.

The liquid that is supplied by the first supply mechanism 80 and the second supply mechanism 85 includes pure water or water with additives added thereto. The additives include, for example, a surfactant, glycerin, and alcohol. The air that is supplied by the first supply mechanism 80 and the second supply mechanism 85 includes compressed air, for example.

As illustrated in FIG. 1, a thickness measuring unit 60 is disposed on an upper surface of the base block 10 laterally of the opening 13. The thickness measuring unit 60 can measure the thickness of the wafer 100 held on the holding surface 22 of the chuck table 20.

The thickness measuring unit 60 includes a contact-type or non-contact-type height gage, and includes a wafer height measuring instrument 61 and a holding surface height measuring instrument 62. The wafer height measuring instrument 61 measures the height of the wafer 100 held on the holding surface 22. The holding surface height measuring instrument 62 measures the height of the frame surface 24 of the frame 23 that lies flush with the holding surface 22. The thickness measuring unit 60 calculates the thickness of the wafer 100 from the difference between the measured height of the wafer 100 and the measured height of the holding surface 22.

The wafer height measuring instrument 61 measures the height of the wafer 100 by contacting the wafer 100 held on the holding surface 22. The holding surface height measuring instrument 62 measures the height of the frame surface 24 of the frame 23, i.e., the height of the holding surface 22, by contacting the frame surface 24.

The wafer height measuring instrument 61 and the holding surface height measuring instrument 62 may be arranged to measure the height of the wafer 100 and the height of the holding surface 22, respectively, by applying laser beams or sound waves to the wafer 100 and the frame surface 24 and detecting reflected laser beams or reflected sound waves.

Alternatively, the thickness measuring unit 60 may have a single non-contact-type thickness measuring instrument, e.g., a laser-beam-type thickness measuring instrument, rather than the wafer height measuring instrument 61 and the holding surface height measuring instrument 62. The alternative thickness measuring unit 60 applies a laser beam having a wavelength transmittable through the wafer 100 to the wafer 100, detects a reflected laser beam from the lower surface, i.e., the face side 101, of the wafer 100 and a reflected laser beam from the upper surface, i.e., the reverse side 102, of the wafer 100, and measures the thickness of the wafer 100 from the difference between the optical paths followed by the respective reflected laser beams. The non-contact-type thickness measuring instrument may be a spectral interferometric wafer thickness meter for measuring the thickness of the wafer 100 by analyzing an interference between a reflected beam from the lower surface of the wafer 100 and a reflected beam from the upper surface of the wafer 100. The thickness measuring instrument may include a superluminescent diode (SLD) as a light source for emitting measuring light.

The grinding apparatus 1 has a controller 7 including a CPU that carries out arithmetic operations according to control programs and a storage medium such as a memory. The controller 7 includes a first controller 8 and a second controller 9, and controls the components described above of the grinding apparatus 1 to perform a grinding process on the wafer 100 held on the chuck table 20.

The first controller 8 controls the first supply mechanism 80 to supply the first fluid to the wafer 100 and the grindstones 77, controls the Z-axis moving mechanism 50 to move the grindstones 77 and the chuck table 20 in the directions relatively toward each other at a predetermined feed speed, controls the grinding mechanism 70 to rotate the grindstones 77, and controls the wafer holding mechanism 30 to rotate the chuck table 20 and hence the wafer 100, thereby grinding the wafer 100. The second controller 9 controls the first supply mechanism 80 to supply the second fluid to the wafer 100 and the grindstones 77, controls the Z-axis moving mechanism 50 to move the chuck table 20 and the grindstones 77 in the directions relatively toward each other at a predetermined feed speed, controls the grinding mechanism 70 to rotate the grindstones 77, and controls the wafer holding mechanism 30 to rotate the chuck table 20 and hence the wafer 100, thereby grinding the wafer 100.

A first grinding process and a second grinding process controlled by the controller 7, as a method of grinding the wafer 100 on the grinding apparatus 1 according to the present embodiment, will be described hereinbelow. In these first and second grinding processes, the wafer 100 is ground by the contact surfaces of the rotating grindstones 77.

### [First Grinding Process]

The first grinding process is carried out on a wafer 100 whose reverse side 102 is a flat surface to be ground, for example.

### [Holding Step]

In the holding step, the operator or a delivery device, not illustrated, for example, places the wafer 100 on the holding surface 22 of the chuck table 20 with the reverse side 102 facing upwardly. The controller 7 controls the suction source to apply a suction force to the holding surface 22, holding the wafer 100 under suction on the holding surface 22.

### [Self-Sharpening-Accelerated Grinding Step]

Then, a self-sharpening-accelerated grinding step is carried out. In the self-sharpening-accelerated grinding step, the first fluid for accelerating the self-sharpening of the lower surfaces, i.e., the contact surfaces, of the grindstones 77 is supplied to the grindstones 77, and the grindstones 77 grind the wafer 100. The lower surfaces of the grindstones 77 represent an example of the contact surfaces of the grindstones 77.

Self-sharpening means that the exposed abrasive grains are dislodged from the contact surfaces, e.g., the lower surfaces, of the grindstones 77 held in abrasive contact with the wafer 100, causing new abrasive grains to emerge on the contact surfaces and provide new cutting edges to keep a sharp grinding ability of the grindstones 77. In the self-sharpening-accelerated grinding step, therefore, the grindstones 77 grind the wafer 100 in a manner to accelerate such a self-sharpening process.

Specifically, in the self-sharpening-accelerated grinding step, the first controller 8 of the controller 7 controls the first supply mechanism 80 to supply the first fluid to the wafer 100 and the grindstones 77, controls the Z-axis moving mechanism 50 to move the chuck table 20 and the grindstones 77 in the directions relatively toward each other at a predetermined feed speed, controls the grinding mechanism 70 to rotate the grindstones 77, and controls the wafer holding mechanism 30 to rotate the chuck table 20 and hence the wafer 100, thereby grinding the wafer 100. According to the present embodiment, the first controller 8 controls the first supply mechanism 80 to supply the first fluid to the grindstones 77 and the reverse side 102 of the wafer 100, controls the Z-axis moving mechanism 50 to move the grinding mechanism 70 including the grindstones 77 toward the chuck table 20 along the Z-axis perpendicular to the holding surface 22, controls the grinding mechanism 70 to rotate the grindstones 77, and controls the wafer holding mechanism 30 to rotate the chuck table 20 and hence the wafer 100, thereby grinding the reverse side 102 of the wafer 100.

More specifically, the first controller 8 controls the Z-axis moving mechanism 50 to position the grindstones 77 at a home vertical position or height. The home vertical position or height is located above the center of rotation of the wafer 100 held on the holding surface 22 of the chuck table 20. The lower surfaces of the grindstones 77 are kept out of contact with the wafer 100 in the home vertical position or height.

Furthermore, the first controller 8 controls the spindle motor 73 to rotate the grindstones 77 and also controls the chuck table motor 34 to rotate the holding surface 22 of the chuck table 20 that is holding the wafer 100 thereon. The grindstones 77 are rotated at a rotational speed of 2000 rpm, for example, whereas the chuck table 20 is rotated at a rotational speed of 120 rpm, for example.

At this time, the first controller 8 also controls the first supply mechanism 80 to start supplying the first fluid from the first liquid source 81 to the wafer 100 and the grindstones 77. The first fluid is supplied at a preset first flow rate. According to the present embodiment, the preset first flow rate is relatively low, e.g., in the range of 0.1 to 1.0 L/min.

Then, the first controller 8 controls the Z-axis moving mechanism 50 to move the grindstones 77 from the home vertical position toward the chuck table 20 along the Z-axis.

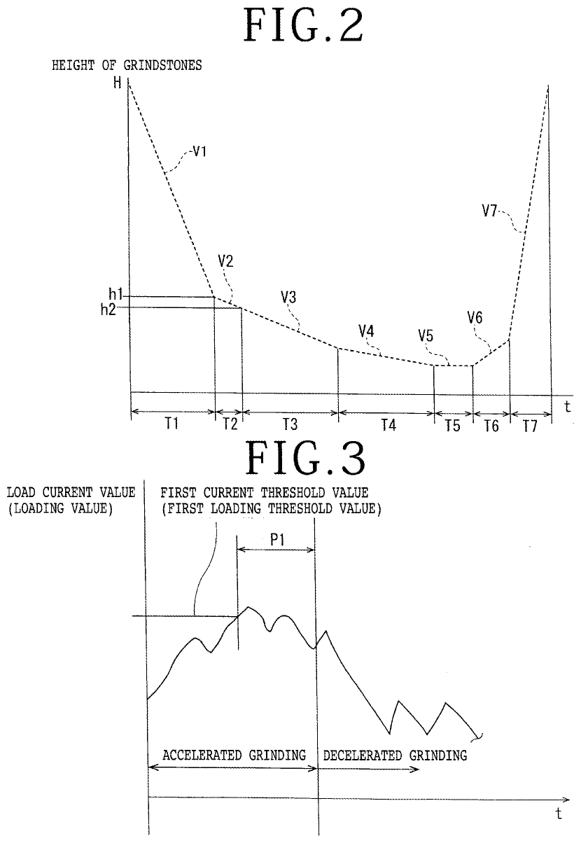

FIG. 2 illustrates a relation between the height H (indicated by the broken-line curve) of the lower surfaces of the grindstones 77 and time t. As illustrated in FIG. 2, the first controller 8 controls the Z-axis moving mechanism 50 to lower the grinding mechanism 70 toward the chuck table 20 at a relatively high initial speed V1 until the lower surfaces of grindstones 77 reach a predetermined air-cutting start height h1 (time zone T1). The first controller 8 can detect the height of the grindstones 77 and its changes using the Z-axis encoder 55 of the Z-axis moving mechanism 50, for example.

After the lower surfaces of grindstones 77 have reached the predetermined air-cutting start height h1, the first controller 8 sets the speed at which the Z-axis moving mechanism 50 lowers the grinding mechanism 70 to an air-cutting speed V2 lower than the initial speed V1. Then, the first controller 8 controls the Z-axis moving mechanism 50 to move the grinding mechanism 70 toward the chuck table 20 at the air-cutting speed V2 (time zone T2).

After the lower surfaces of the grindstones 77 have reached a height h2 where the lower surfaces of the grindstones 77 contact the reverse side 102 of the wafer 100, the first controller 8 controls the Z-axis moving mechanism 50 to lower the grindstones 77 to grind the reverse side 102 of the wafer 100 at a first grinding speed V3 (time zone T3). The first grinding speed V3 is lower than the initial speed V1 and is equal to the air-cutting speed V2, for example.

While the grindstones 77 are grinding the reverse side 102 of the wafer 100, the first controller 8 continuously monitors the load current value of the spindle motor 73 as measured by the load current value measuring unit 78, the vertical loading value of the grindstones 77 as measured by the loading value measuring unit 36, and the amount of downward movement of the lower surfaces of the grindstones 77 after they have contacted the wafer 100.

In FIG. 2, the broken-line curve represents the height H of the lower surfaces of the grindstones 77. As the grindstones 77 are lowered into contact with the wafer 100 in the manner described above, the load current value of the spindle motor 73 and the vertical loading value of the grindstones 77 undergo changes.

The amount of downward movement of the lower surfaces of the grindstones 77 is determined from changes in the height (h) of the lower surfaces of the grindstones 77 represented by the broken-line curve in FIG. 2 that are measured using the Z-axis encoder 55 of the Z-axis moving mechanism 50.

The first controller 8 detects the thickness of the wafer 100 being ground that is measured by the thickness measuring unit 60. When the thickness of the wafer 100 approaches a target thickness that represents a preset thickness, the first controller 8 controls the Z-axis moving mechanism 50 to move the grinding mechanism 70 toward the chuck table 20 at a second grinding speed V4 lower than the first grinding speed V3 (time zone T4). In other words, the first controller 8 continues to perform the first grinding process by reducing the speed at which the grinding mechanism 70 is lowered from the first grinding speed V3 to the second grinding speed V4. The second grinding speed V4 is 0.2 μm/sec., for example.

In the self-sharpening-accelerated grinding step, the wafer 100 is ground while the first fluid is being supplied to the wafer 100 and the grindstones 77 at the first flow rate that is relatively low. Consequently, the cooling of the grindstones 77 is restrained, thereby accelerating the self-sharpening of the grindstones 77.

As described above, the wafer 100 that is to be ground in the first grinding process has the reverse side 102 that is a flat surface to be ground. Inasmuch as the load current value of the spindle motor 73 and the vertical loading value of the grindstones 77 tend to be high when the reverse side 102 of the wafer 100 is ground, the reverse side 102 can be well ground by accelerating the self-sharpening of the grindstones 77.

While the wafer 100 is being ground at the second grinding speed V4 in the self-sharpening-accelerated grinding step, the first controller 8 decides whether a predetermined period of time has elapsed or not after the load current value of the spindle motor 73 that rotates the grindstones 77 that are grinding the wafer 100 reached a preset first current threshold value, decides whether a predetermined period of time has elapsed or not after the vertical loading value of the grindstones 77 reached a preset first loading threshold value, and decides whether the lower surfaces of the grindstones 77 have further been moved, i.e., lowered, in a direction toward the wafer 100 by a predetermined distance or not after having contacted the wafer 100 in the self-sharpening-accelerated grinding step.

If the predetermined period of time has elapsed after the load current value of the spindle motor 73 reached the first current threshold value, or if the predetermined period of time has elapsed after the vertical loading value of the grindstones 77 reached the first loading threshold value, or if the lower surfaces of the grindstones 77 have further been moved, i.e., lowered, in the direction toward the wafer 100 by the predetermined distance after having contacted the wafer 100 in the self-sharpening-accelerated grinding step, then the first controller 8 finishes the self-sharpening-accelerated grinding step, and the second controller 9 carries out a self-sharpening-decelerated grinding step. In other words, the first grinding process transitions from the self-sharpening-accelerated grinding step to the self-sharpening-decelerated grinding step, and the second controller 9 takes over from the first controller 8 for the control of the grinding apparatus 1.

FIG. 3 is a graph illustrating an example of time-dependent changes in load current values and loading values in the time zone T4 illustrated in FIG. 2. The self-sharpening-accelerated grinding step may transition to the self-sharpening-decelerated grinding step in the time zone T3 rather than the time zone T4.

As illustrated in FIG. 3, the self-sharpening-accelerated grinding step transitions to the self-sharpening-decelerated grinding step, for example, when a predetermined period P1 of time has elapsed after the load current value of the spindle motor 73 reached the preset first current threshold value or after the vertical loading value of the grindstones 77 reached the preset first loading threshold value. The predetermined period P1 of time is preset in the first controller 8 and the second controller 9, for example.

Specifically, the reverse side 102 of the wafer 100 that is a relatively flat surface turns into a rough surface having surface irregularities as it is progressively ground. When the predetermined period of time has elapsed after the load current value reached the first current threshold value, or when the predetermined period of time has elapsed after the vertical loading value reached the first loading threshold value, or when the lower surfaces of the grindstones 77 have further been moved, i.e., lowered, in the direction toward the wafer 100 by the predetermined distance after having contacted the wafer 100, the reverse side 102 of the wafer 100 has been roughened to the extent that the grindstones 77 are capable of grinding the reverse side 102 well even though the self-sharpening of the grindstones 77 is not accelerated. At this time, therefore, the first grinding process transitions to the self-sharpening-decelerated grinding step. The surface irregularities of the reverse side 102 are thus prevented from causing a lot of abrasive grains to drop out of the grindstones 77 and hence from unduly wearing the grindstones 77.

The relatively flat reverse side 102 of the wafer 100 that is to be ground in the first grinding process where the self-sharpening-accelerated grinding step precedes the self-sharpening-decelerated grinding step has a surface roughness (Ra) of less than 100 nm (Ra<100 nm), for example, in an initial state, i.e., before the wafer 100 is ground. Stated otherwise, it may be decided whether the first grinding process is to be performed on the wafer 100 or not by ascertaining whether the surface roughness (Ra) of the reverse side 102 of the wafer 100 is less than 100 nm or not, for example.

The predetermined period P1 of time illustrated in FIG. 3 may be 0 second. In this case, when the load current value of the spindle motor 73 has reached the preset first current threshold value, or when the vertical loading value of the grindstones 77 has reached the preset first loading threshold value, or when the lower surfaces of the grindstones 77 have further been moved, i.e., lowered, in the direction toward the wafer 100 by the predetermined distance after having contacted the wafer 100 in the self-sharpening-accelerated grinding step, the first grinding process transitions from the self-sharpening-accelerated step to the self-sharpening-decelerated grinding step.

According to the present embodiment, therefore, when the load current value of the spindle motor 73 has reached the preset first current threshold value or when the predetermined period of time has elapsed after the load current value of the spindle motor 73 reached the preset first current threshold value, or when the vertical loading value of the grindstones 77 has reached the preset first loading threshold value or when the predetermined period of time has elapsed after the vertical loading value of the grindstones 77 reached the preset first loading threshold value, or when the lower surfaces of the grindstones 77 have further been moved, i.e., lowered, in the direction toward the wafer 100 by the predetermined distance after having contacted the wafer 100 in the self-sharpening-accelerated grinding step, the self-sharpening-accelerated grinding step transitions to the self-sharpening-decelerated grinding step.

### [Self-Sharpening-Decelerated Grinding Step]

In the self-sharpening-decelerated grinding step, the second fluid is supplied to decelerate the self-sharpening of the lower surfaces, i.e., the contact surfaces, of the grindstones 77, and the grindstones 77 grind the wafer 100 to the target thickness that represents the preset thickness. In the self-sharpening-decelerated grinding step, the grindstones 77 grind the wafer 100 in a manner to decelerate the self-sharpening process described above.

Specifically, in the self-sharpening-decelerated grinding step, the second controller 9 of the controller 7 controls the first supply mechanism 80 to supply the second fluid to the wafer 100 and the grindstones 77, controls the Z-axis moving mechanism 50 to move the chuck table 20 and the grindstones 77 in the directions relatively toward each other at a predetermined feed speed, controls the grinding mechanism 70 to rotate the grindstones 77, and controls the wafer holding mechanism 30 to rotate the chuck table 20 and hence the wafer 100, thereby grinding the wafer 100. According to the present embodiment, the second controller 9 controls the first supply mechanism 80 to supply the first fluid to the grindstones 77 and the reverse side 102 of the wafer 100, controls the Z-axis moving mechanism 50 to move the grinding mechanism 70 including the grindstones 77 toward the chuck table 20 along the Z-axis perpendicular to the holding surface 22, controls the grinding mechanism 70 to rotate the grindstones 77, and controls the wafer holding mechanism 30 to rotate the chuck table 20 and hence the wafer 100, thereby grinding the reverse side 102 of the wafer 100.

More specifically, the second controller 9 continues the first grinding process while continuously lowering the grinding mechanism 70 at the second grinding speed V4 (see FIG. 2) following the self-sharpening-accelerated grinding step controlled by the first controller 8. At this time, the second controller 9 controls the first supply mechanism 80 to supply the second fluid from the first liquid source 81 to the wafer 100 and the grindstones 77. The second fluid is supplied at a second flow rate that is higher than the preset first flow rate referred to above. According to the present embodiment, the second flow rate is in the range of 4.0 to 5.0 L/min., for example. The second controller 9 grinds the wafer 100 until its thickness reaches the target thickness by having the grindstones 77 slide on the wafer 100 with the second fluid supplied at the second flow rate.

In the self-sharpening-decelerated grinding step, as described above, the first grinding process is carried out while the second fluid is being supplied at the second flow rate higher than the first flow rate to the grindstones 77 and the wafer 100. Therefore, the cooling of the grindstones 77 is promoted, thereby decelerating the self-sharpening of the grindstones 77.

Then, after the thickness of the wafer 100 has reached the target thickness, the second controller 9 stops lowering the grinding mechanism 70 toward the holding surface 22 of the chuck table 20 and keeps the grindstones 77 at the height reached at rest, thereby carrying out what is called a spark-out process (time zone T5), as illustrated in FIG. 2. The spark-out process removes ground thickness differences from the reverse side 102 of the wafer 100.

Thereafter, the second controller 9 controls the Z-axis moving mechanism 50 to slowly lift the grinding mechanism 70 at a preset escape-cutting speed V6, thereby carrying out an escape-cutting process (time zone T6). The controller 7 continuously carries out the escape-cutting process until the grindstones 77 move out of contact with the reverse side 102 of the wafer 100.

After the escape-cutting process has ended, the second controller 9 controls the Z-axis moving mechanism 50 to retract the grinding mechanism 70 upwardly to the home vertical position at a relatively high retraction speed V7 (time zone T7). The first grinding process now comes to an end.

According to the present embodiment, as described above, the first grinding process is carried out by switching between the self-sharpening-accelerated grinding step controlled by the first controller 8 and the self-sharpening-decelerated grinding step controlled by the second controller 9 on the basis of the load current value of the spindle motor 73, the vertical loading value of the grindstones 77, or the distance that the lower surfaces of the grindstones 77 are lowered. Therefore, compared to grinding the wafer 100 only in the self-sharpening-accelerated grinding step, abrasive grains dislodged from the grindstones 77 are reduced, and the amount of wear of the grindstones 77 is restrained. In addition, compared to grinding the wafer 100 only in the self-sharpening-decelerated grinding step, the fluids supplied to the grindstones 77 are saved, the time required to grind the wafer 100 is shortened, and the processing quality of the wafer 100 is increased. According to the present embodiment, therefore, when the wafer 100 is ground, abrasive grains dropping off from grindstones 77 are minimized, and hence undue wear on the grindstones 77 is restrained while at the same time maintaining a desired level of the processing quality of the ground surface of the wafer 100, resulting in a reduction in the frequency at which the grinding wheel 75 is replaced.

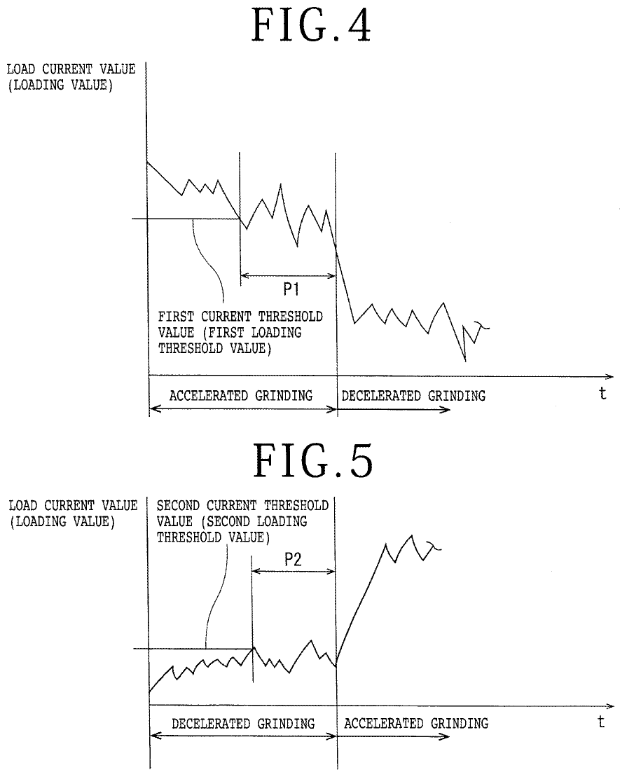

FIG. 4 is a graph illustrating another example of time-dependent changes in load current values and loading values in the time zone T4. The self-sharpening-accelerated grinding step may transition to the self-sharpening-decelerated grinding step in the time zone T3 rather than the time zone T4.

As illustrated in FIG. 4, the self-sharpening-accelerated grinding step may transition to the self-sharpening-decelerated grinding step, for example, when the load current value of the spindle motor 73 has become smaller than a preset first current threshold value or a predetermined period of time has elapsed after the load current value of the spindle motor 73 became smaller than the preset first current threshold value, or when the vertical loading value of the grindstones 77 has become smaller than a preset first loading threshold value or a predetermined period of time has elapsed after the vertical loading value of the grindstones 77 became smaller than the preset first loading threshold value, or when the lower surfaces, i.e., the contact surfaces, of the grindstones 77 have further been moved, i.e., lowered, in the direction toward the wafer 100 by a predetermined distance after having contacted the wafer 100 in the self-sharpening-accelerated grinding step.

According to the present embodiment, furthermore, the distance that the lower surfaces of the grindstones 77 are lowered may not be taken into account for making a transition from the self-sharpening-accelerated grinding step to the self-sharpening-decelerated grinding step. In this case, the self-sharpening-accelerated grinding step transitions to the self-sharpening-decelerated grinding step, i.e., the control process carried out by the first controller 8 transitions to the control process carried out by the second controller 9, when the load current value measured by the load current value measuring unit 78 has reached a preset first current threshold value or a predetermined period of time has elapsed after the load current value measured by the load current value measuring unit 78 reached the preset first current threshold value, or when the vertical loading value measured by the loading value measuring unit 36 has reached a preset first loading threshold value or a predetermined period of time has elapsed after the vertical loading value measured by the loading value measuring unit 36 reached the preset first loading threshold value.

In this case, the self-sharpening-accelerated grinding step may transition to the self-sharpening-decelerated grinding step, i.e., the control process carried out by the first controller 8 may transition to the control process carried out by the second controller 9, when the load current value measured by the load current value measuring unit 78 has reached the preset first current threshold value or the predetermined period of time has elapsed after the load current value measured by the load current value measuring unit 78 reached the preset first current threshold value, and when the vertical loading value measured by the loading value measuring unit 36 has reached the preset first loading threshold value or the predetermined period of time has elapsed after the vertical loading value measured by the loading value measuring unit 36 reached the preset first loading threshold value.

Moreover, in this case, as illustrated in FIG. 4, the self-sharpening-accelerated grinding step may transition to the self-sharpening-decelerated grinding step when the load current value of the spindle motor 73 has become smaller than the preset first current threshold value or the predetermined period of time has elapsed after the load current value of the spindle motor 73 became smaller than the preset first current threshold value, and when the vertical loading value of the grindstones 77 has become smaller than the preset first loading threshold value or the predetermined period of time has elapsed after the vertical loading value of the grindstones 77 became smaller than the preset first loading threshold value.

According to the present embodiment, furthermore, the grinding apparatus 1 may be dispensed with the loading value measuring unit 36. In this case, the self-sharpening-accelerated grinding step may transition to the self-sharpening-decelerated grinding step, i.e., the control process carried out by the first controller 8 may transition to the control process carried out by the second controller 9, when the load current value measured by the load current value measuring unit 78 has reached the preset first current threshold value or the predetermined period of time has elapsed after the load current value measured by the load current value measuring unit 78 reached the preset first current threshold value.

In addition, the load current value of the spindle motor 73 and the vertical loading value of the grindstones 77 may not be taken into account for making a transition from the self-sharpening-accelerated grinding step to the self-sharpening-decelerated grinding step. In this case, the self-sharpening-accelerated grinding step transitions to the self-sharpening-decelerated grinding step, i.e., the control process carried out by the first controller 8 transitions to the control process carried out by the second controller 9, when the lower surfaces of the grindstones 77 have further been moved, i.e., lowered, in the direction toward the wafer 100 by the predetermined distance after having contacted the wafer 100 in the self-sharpening-accelerated grinding step.

Moreover, the self-sharpening-accelerated grinding step may transition to the self-sharpening-decelerated grinding step on the basis of the thickness of the wafer 100 measured by the thickness measuring unit 60. In this case, in the self-sharpening-accelerated grinding step, the first controller 8 grinds the wafer 100 with the grindstones 77 while supplying the first fluid and measuring the thickness of the wafer 100 with the thickness measuring unit 60. Then, the self-sharpening-accelerated grinding step transitions to the self-sharpening-decelerated grinding step, i.e., the control process carried out by the first controller 8 transitions to the control process carried out by the second controller 9, when the thickness value of the wafer 100 measured by the thickness measuring unit 60 has reached a preset first thickness threshold value.

Providing the self-sharpening-accelerated grinding step transitions to the self-sharpening-decelerated grinding step on the basis of the thickness of the wafer 100 measured by the thickness measuring unit 60, the thickness measuring unit 60 may measure the thickness of the wafer 100 while the self-sharpening-accelerated grinding step is suspended, i.e., temporarily interrupted.

In this case, in the self-sharpening-accelerated grinding step, the first controller 8 supplies the first fluid for accelerating the self-sharpening of the lower surfaces of the grindstones 77 and grinds the wafer 100 with the grindstones 77 until the lower surfaces of the grindstones 77 have further been moved, i.e., lowered, in the direction toward the wafer 100 by the predetermined distance after having contacted the wafer 100.

Thereafter, the first controller 8 carries out a thickness measuring step of stopping rotating the grindstones 77 and the chuck table 20 and measuring the thickness of the wafer 100 ground in the self-sharpening-accelerated grinding step with the thickness measuring unit 60. If the thickness measured in the thickness measuring step has not reached the first thickness threshold value, then the first controller 8 carries out a regrinding step of carrying out the self-sharpening-accelerated grinding step again. Specifically, the first controller 8 supplies the first fluid and grinds the wafer 100 with the grindstones 77 until the grindstones 77 are further moved in the direction toward the wafer 100, i.e., lowered, by a distance represented by the difference between the thickness measured in the thickness measuring step and the first thickness threshold value. Thereafter, the first controller 8 carries out the thickness measuring step again to confirm the thickness of the wafer 100, for example.

If the thickness measured in the thickness measuring step has reached the first thickness threshold value, then the self-sharpening-accelerated grinding step transitions to the self-sharpening-decelerated grinding step, i.e., the control process carried out by the first controller 8 transitions to the control process carried out by the second controller 9. In other words, the second controller 9 carries out the self-sharpening-decelerated grinding step of supplying the second fluid for restraining the self-sharpening of the lower surfaces of the grindstones 77 and grinding the wafer 100 to the preset thickness with the grindstones 77.

This process is effective when it is difficult to measure the thickness of the wafer 100 while the wafer 100 is being ground, as when the reverse side 102 of the wafer 100 has large surface irregularities. The first thickness threshold value is not limited to a particular thickness, but may represent a predetermined thickness range.

The reverse side 102 of the wafer 100 may be regarded as having large surface irregularities if structures with large steps are formed on the reverse side 102 of the wafer 100 and if a plurality of workpieces are disposed at spaced intervals on the reverse side 102 (multi-mount), for example.

According to the present embodiment, the first controller 8 decides whether the load current value of the spindle motor 73 that rotates the grindstones 77 that are grinding the wafer 100 has reached the preset first current threshold value or not or the predetermined period of time has elapsed or not after the load current value of the spindle motor 73 reached the preset first current threshold value, whether the vertical loading value of the grindstones 77 has reached the preset first loading threshold value or not or the predetermined period of time has elapsed or not after the vertical loading value of the grindstones 77 reached the preset first loading threshold value, and whether the lower surfaces, i.e., the contact surfaces, of the grindstones 77 have further been moved, i.e., lowered, in the direction toward the wafer 100 by the predetermined distance or not after having contacted the wafer 100 in the self-sharpening-accelerated grinding step, while the wafer 100 is being ground at the second grinding speed V4 in the self-sharpening-accelerated grinding step. However, the first controller 8 may make the above decision at any desired timing in the self-sharpening-accelerated grinding step, rather than while the wafer 100 is being ground at the second grinding speed V4.

### [Second Grinding Process]

The second grinding process is carried out on a wafer 100 whose reverse side 102 has surface irregularities to be ground, for example.

### [Holding Step]

In the holding step, as with the first grinding process, the operator or the like places the wafer 100 on the holding surface 22 of the chuck table 20 with the reverse side 102 facing upwardly. The controller 7 controls the suction source to apply a suction force to the holding surface 22, holding the wafer 100 under suction on the holding surface 22.

### [Self-Sharpening-Decelerated Grinding Step]

Then, the self-sharpening-decelerated grinding step is carried out. In the self-sharpening-decelerated grinding step, the second fluid for decelerating the self-sharpening of the lower surfaces, i.e., the contact surfaces, of the grindstones 77 is supplied to the grindstones 77, and the grindstones 77 grind the wafer 100. The grindstones 77 grind the wafer 100 in a manner to restrain the self-sharpening described above.

Specifically, in the self-sharpening-decelerated grinding step, the second controller 9 of the controller 7 controls the first supply mechanism 80 to supply the second fluid to the wafer 100 and the grindstones 77, controls the Z-axis moving mechanism 50 to move the chuck table 20 and the grindstones 77 in the directions relatively toward each other at a predetermined feed speed, controls the grinding mechanism 70 to rotate the grindstones 77, and controls the wafer holding mechanism 30 to rotate the chuck table 20 and hence the wafer 100, thereby grinding the wafer 100. According to the present embodiment, the second controller 9 controls the first supply mechanism 80 to supply the second fluid to the grindstones 77 and the reverse side 102 of the wafer 100, controls the Z-axis moving mechanism 50 to move the grinding mechanism 70 including the grindstones 77 toward the chuck table 20 along the Z-axis perpendicular to the holding surface 22, controls the grinding mechanism 70 to rotate the grindstones 77, and controls the wafer holding mechanism 30 to rotate the chuck table 20 and hence the wafer 100, thereby grinding the reverse side 102 of the wafer 100.

More specifically, the second controller 9 controls the Z-axis moving mechanism 50 to position the grindstones 77 at the home vertical position or height referred to above. Furthermore, the second controller 9 controls the spindle motor 73 to rotate the grindstones 77 and also controls the chuck table motor 34 to rotate the holding surface 22 of the chuck table 20 that is holding the wafer 100 thereon.

At this time, the second controller 9 also controls the first supply mechanism 80 to start supplying the second fluid at a preset second flow rate from the first liquid source 81 to the wafer 100 and the grindstones 77.

Then, the second controller 9 controls the Z-axis moving mechanism 50 to move the grindstones 77 from the home vertical position toward the chuck table 20 along the Z-axis. The second controller 9 controls the Z-axis moving mechanism 50 to lower the grinding mechanism 70 toward the chuck table 20 at the relatively high initial speed V1 until the lower surfaces of grindstones 77 reach the predetermined air-cutting start height h1 illustrated in FIG. 2 (time zone T1).

After the lower surfaces of grindstones 77 have reached the predetermined air-cutting start height h1, the second controller 9 sets the speed at which the Z-axis moving mechanism 50 lowers the grinding mechanism 70 to the air-cutting speed V2 lower than the initial speed V1. Then, the second controller 9 controls the Z-axis moving mechanism 50 to move the grinding mechanism 70 toward the chuck table 20 at the air-cutting speed V2 (time zone T2).

After the lower surfaces of the grindstones 77 have reached the height h2 where the lower surfaces of the grindstones 77 contact the reverse side 102 of the wafer 100, the second controller 9 controls the Z-axis moving mechanism 50 to lower the grindstones 77 to grind the reverse side 102 of the wafer 100 at the first grinding speed V3 (time zone T3). The first grinding speed V3 is lower than the initial speed V1 and is equal to the air-cutting speed V2, for example.

While the grindstones 77 are grinding the reverse side 102 of the wafer 100, the second controller 9 continuously monitors the load current value of the spindle motor 73 as measured by the load current value measuring unit 78, the vertical loading value of the grindstones 77 as measured by the loading value measuring unit 36, and the amount of downward movement of the lower surfaces of the grindstones 77 after they have contacted the wafer 100.

The second controller 9 detects the thickness of the wafer 100 being ground that is measured by the thickness measuring unit 60. When the thickness of the wafer 100 approaches the target thickness that represents the preset thickness, the second controller 9 controls the Z-axis moving mechanism 50 to move the grinding mechanism 70 toward the chuck table 20 at the second grinding speed V4 lower than the first grinding speed V3 (time zone T4). In other words, the second controller 9 continues to perform the second grinding process by reducing the speed at which the grinding mechanism 70 is lowered from the first grinding speed V3 to the second grinding speed V4.

In the self-sharpening-decelerated grinding step, as described above, the wafer 100 is ground while the second fluid is being supplied to the wafer 100 and the grindstones 77 at the second flow rate that is relatively high. Consequently, the cooling of the grindstones 77 is accelerated, thereby decelerating the self-sharpening of the grindstones 77.

As described above, the wafer 100 that is to be ground in the second grinding process has the reverse side 102 that has surface irregularities. Inasmuch as the load current value of the spindle motor 73 and the vertical loading value of the grindstones 77 are less likely to increase when the reverse side 102 of the wafer 100 is ground, the reverse side 102 can be well ground without accelerating the self-sharpening of the grindstones 77. Furthermore, since the reverse side 102 of the wafer 100 functions as a dresser board, the grindstones 77 are likely to be self-sharpened. Therefore, by performing the second grinding process in which the self-sharpening of the grindstones 77 is restrained, the wafer 100 can be well ground and the amount of wear of the grindstones 77 is restrained.

While the wafer 100 is being ground at the second grinding speed V4 in the self-sharpening-decelerated grinding step, the second controller 9 decides whether a predetermined period of time has elapsed or not after the load current value of the spindle motor 73 that rotates the grindstones 77 that are grinding the wafer 100 reached a preset second current threshold value, decides whether a predetermined period of time has elapsed or not after the vertical loading value of the grindstones 77 reached a preset second loading threshold value, and decides whether the lower surfaces of the grindstones 77 have further been moved, i.e., lowered, in the direction toward the wafer 100 by a predetermined distance or not after having contacted the wafer 100 in the self-sharpening-decelerated grinding step.

If the predetermined period of time has elapsed after the load current value of the spindle motor 73 reached the second current threshold value, or if the predetermined period of time has elapsed after the vertical loading value of the grindstones 77 reached the second loading threshold value, or if the lower surfaces of the grindstones 77 have further been moved, i.e., lowered, in the direction toward the wafer 100 by the predetermined distance after having contacted the wafer 100 in the self-sharpening-decelerated grinding step, then the second controller 9 finishes the self-sharpening-decelerated grinding step, and the first controller 8 carries out the self-sharpening-accelerated grinding step. In other words, the second grinding process transitions from the self-sharpening-decelerated grinding step to the self-sharpening-accelerated grinding step, and the first controller 8 takes over from the second controller 9 for the control of the grinding apparatus 1.

FIG. 5 is a graph illustrating an example of time-dependent changes in load current values and loading values in the time zone T4 illustrated in FIG. 2. The self-sharpening-decelerated grinding step may transition to the self-sharpening-accelerated grinding step in the time zone T3 rather than the time zone T4.

As illustrated in FIG. 5, the self-sharpening-decelerated grinding step transitions to the self-sharpening-accelerated grinding step, for example, when a predetermined period P2 of time has elapsed after the load current value of the spindle motor 73 reached the preset second current threshold value or after the vertical loading value of the grindstones 77 reached the preset second loading threshold value. The predetermined period P2 of time is preset in the first controller 8 and the second controller 9, for example.

The reverse side 102 of the wafer 100 that has surface irregularities becomes a flatter surface as it is progressively ground. When the predetermined period of time has elapsed after the load current value reached the first current threshold value, or when the predetermined period of time has elapsed after the vertical loading value reached the first loading threshold value, or when the lower surfaces of the grindstones 77 have further been moved, i.e., lowered, in the direction toward the wafer 100 by the predetermined distance after having contacted the wafer 100, the reverse side 102 of the wafer 100 has been flattened to the extent that it can be well ground by accelerating the self-sharpening of the grindstones 77. Therefore, the second grinding process transitions to the self-sharpening-accelerated grinding step at this time.

The reverse side 102 with surface irregularities of the wafer 100 that is to be ground in the second grinding process where the self-sharpening-decelerated grinding step precedes the self-sharpening-accelerated grinding step has height differences of 10 μm or larger between the surface irregularities, for example, in an initial state, i.e., before the wafer 100 is ground. Stated otherwise, it may be decided whether the second grinding process is to be performed on the wafer 100 or not by ascertaining whether or not the height differences between the surface irregularities of the reverse side 102 are 10 μm or larger, for example.

The predetermined period P2 of time illustrated in FIG. 5 may be 0 second. In this case, when the load current value of the spindle motor 73 has reached the preset second current threshold value, or when the vertical loading value of the grindstones 77 has reached the preset second loading threshold value, or when the lower surfaces of the grindstones 77 have further been moved, i.e., lowered, in the direction toward the wafer 100 by the predetermined distance after having contacted the wafer 100 in the self-sharpening-decelerated grinding step, the second grinding process transitions from the self-sharpening-decelerated grinding step to the self-sharpening-accelerated grinding step.

According to the present embodiment, therefore, when the load current value of the spindle motor 73 has reached the preset second current threshold value or when the predetermined period of time has elapsed after the load current value of the spindle motor 73 reached the preset second current threshold value, or when the vertical loading value of the grindstones 77 has reached the preset second loading threshold value or when the predetermined period of time has elapsed after the vertical loading value of the grindstones 77 reached the preset second loading threshold value, or when the lower surfaces of the grindstones 77 have further been moved, i.e., lowered, in the direction toward the wafer 100 by the predetermined distance after having contacted the wafer 100 in the self-sharpening-decelerated grinding step, the self-sharpening-decelerated grinding step transitions to the self-sharpening-accelerated grinding step.

### [Self-Sharpening-Accelerated Grinding Step]

In the self-sharpening-accelerated grinding step, the first fluid is supplied to decelerate the self-sharpening of the lower surfaces, i.e., the contact surfaces, of the grindstones 77, and the grindstones 77 grind the wafer 100 to the target thickness that represents the preset thickness. In the self-sharpening-accelerated grinding step, the grindstones 77 grind the wafer 100 in a manner to accelerate the self-sharpening process described above.

Specifically, in the self-sharpening-accelerated grinding step, the first controller 8 of the controller 7 controls the first supply mechanism 80 to supply the first fluid to the wafer 100 and the grindstones 77, controls the Z-axis moving mechanism 50 to move the chuck table 20 and the grindstones 77 in the directions relatively toward each other at a predetermined feed speed, controls the grinding mechanism 70 to rotate the grindstones 77, and controls the wafer holding mechanism 30 to rotate the chuck table 20 and hence the wafer 100, thereby grinding the wafer 100. According to the present embodiment, the first controller 8 controls the first supply mechanism 80 to supply the first fluid to the grindstones 77 and the reverse side 102 of the wafer 100, controls the Z-axis moving mechanism 50 to move the grinding mechanism 70 including the grindstones 77 toward the chuck table 20 along the Z-axis perpendicular to the holding surface 22, controls the grinding mechanism 70 to rotate the grindstones 77, and controls the wafer holding mechanism 30 to rotate the chuck table 20 and hence the wafer 100, thereby grinding the reverse side 102 of the wafer 100.

More specifically, the first controller 8 continues the second grinding process while continuously lowering the grinding mechanism 70 at the second grinding speed V4 following the self-sharpening-decelerated grinding step controlled by the second controller 9. At this time, the first controller 8 controls the first supply mechanism 80 to supply the first fluid from the first liquid source 81 to the wafer 100 and the grindstones 77. The first fluid is supplied at the first flow rate that is lower than the second flow rate, as described above.

In the self-sharpening-accelerated grinding step, the second grinding process is carried out while the first fluid is being supplied at the first flow rate lower than the second flow rate to the grindstones 77 and the wafer 100. Therefore, the self-sharpening of the grindstones 77 is promoted.

Then, after the thickness of the wafer 100 has reached the target thickness, the first controller 8 stops lowering the grinding mechanism 70 toward the holding surface 22 of the chuck table 20 and keeps the grindstones 77 at the height reached at rest, thereby carrying out the spark-out process (time zone T5).

Thereafter, the first controller 8 controls the Z-axis moving mechanism 50 to slowly lift the grinding mechanism 70 at the preset escape-cutting speed V6, thereby carrying out the escape-cutting process (time zone T6). The controller 7 continuously carries out the escape-cutting process until the grindstones 77 move out of contact with the reverse side 102 of the wafer 100.

After the escape-cutting process has ended, the first controller 8 controls the Z-axis moving mechanism 50 to retract the grinding mechanism 70 upwardly to the home vertical position at the relatively high retraction speed V7 (time zone T7 in FIG. 2). The second grinding process now comes to an end.

As described above, the second grinding process is carried out by switching between the self-sharpening-accelerated grinding step controlled by the first controller 8 and the self-sharpening-decelerated grinding step controlled by the second controller 9 on the basis of the load current value of the spindle motor 73, the vertical loading value of the grindstones 77, or the distance that the lower surfaces of the grindstones 77 are lowered. Therefore, compared to grinding the wafer 100 only in the self-sharpening-accelerated grinding step, abrasive grains dislodged from the grindstones 77 are reduced, and the amount of wear of the grindstones 77 is restrained. In addition, compared to grinding the wafer 100 only in the self-sharpening-decelerated grinding step, the fluids supplied to the grindstones 77 are saved, the time required to grind the wafer 100 is shortened, and the processing quality of the wafer 100 is increased. According to the present embodiment, therefore, when the wafer 100 is ground, abrasive grains dropping off from grindstones 77 are minimized, and hence undue wear on the grindstones 77 is restrained while at the same time maintaining a desired level of the processing quality of the ground surface of the wafer 100, resulting in a reduction in the frequency at which the grinding wheel 75 is replaced.

As illustrated in FIG. 5, the self-sharpening-decelerated grinding step may transition to the self-sharpening-accelerated grinding step, for example, when the load current value of the spindle motor 73 has become larger than a preset second current threshold value or a predetermined period of time has elapsed after the load current value of the spindle motor 73 became larger than the preset second current threshold value, or when the vertical loading value of the grindstones 77 has become larger than a preset second loading threshold value or a predetermined period of time has elapsed after the vertical loading value of the grindstones 77 became larger than the preset second loading threshold value, or when the lower surfaces, i.e., the contact surfaces, of the grindstones 77 have further been moved, i.e., lowered, in the direction toward the wafer 100 by a predetermined distance after having contacted the wafer 100 in the self-sharpening-decelerated grinding step.

According to the present embodiment, furthermore, the distance that the lower surfaces of the grindstones 77 are lowered may not be taken into account for making a transition from the self-sharpening-decelerated grinding step to the self-sharpening-accelerated grinding step. In this case, the self-sharpening-decelerated grinding step transitions to the self-sharpening-accelerated grinding step, i.e., the control process carried out by the second controller 9 transitions to the control process carried out by the first controller 8, when the load current value measured by the load current value measuring unit 78 has reached a preset second current threshold value or a predetermined period of time has elapsed after the load current value measured by the load current value measuring unit 78 reached the preset second current threshold value, or when the vertical loading value measured by the loading value measuring unit 36 has reached a preset second loading threshold value or a predetermined period of time has elapsed after the vertical loading value measured by the loading value measuring unit 36 reached the preset second loading threshold value.

In this case, the self-sharpening-decelerated grinding step transitions to the self-sharpening-accelerated grinding step, i.e., the control process carried out by the second controller 9 may transition to the control process carried out by the first controller 8, when the load current value measured by the load current value measuring unit 78 has reached the preset second current threshold value or the predetermined period of time has elapsed after the load current value measured by the load current value measuring unit 78 reached the preset second current threshold value, and when the vertical loading value measured by the loading value measuring unit 36 has reached the preset second loading threshold value or the predetermined period of time has elapsed after the vertical loading value measured by the loading value measuring unit 36 reached the preset second loading threshold value.

Moreover, in this case, as illustrated in FIG. 5, the self-sharpening-decelerated grinding step may transition to the self-sharpening-accelerated grinding step when the load current value of the spindle motor 73 has become larger than the preset second current threshold value or the predetermined period of time has elapsed after the load current value of the spindle motor 73 became larger than the preset second current threshold value, and when the vertical loading value of the grindstones 77 has become larger than the preset second loading threshold value or the predetermined period of time has elapsed after the vertical loading value of the grindstones 77 became larger than the preset second loading threshold value.

According to the present embodiment, furthermore, the grinding apparatus 1 may be dispensed with the loading value measuring unit 36. In this case, the self-sharpening-decelerated grinding step may transition to the self-sharpening-accelerated grinding step, i.e., the control process carried out by the second controller 9 may transition to the control process carried out by the first controller 8, when the load current value measured by the load current value measuring unit 78 has reached the preset second current threshold value or the predetermined period of time has elapsed after the load current value measured by the load current value measuring unit 78 reached the preset second current threshold value.

In addition, the load current value of the spindle motor 73 and the vertical loading value of the grindstones 77 may not be taken into account for making a transition from the self-sharpening-decelerated grinding step to the self-sharpening-accelerated grinding step. In this case, the self-sharpening-decelerated grinding step transitions to the self-sharpening-accelerated grinding step, i.e., the control process carried out by the second controller 9 transitions to the control process carried out by the first controller 8, when the lower surfaces of the grindstones 77 have further been moved, i.e., lowered, in the direction toward the wafer 100 by the predetermined distance after having contacted the wafer 100 in the self-sharpening-decelerated grinding step.

Moreover, the self-sharpening-decelerated grinding step may transition to the self-sharpening-accelerated grinding step on the basis of the thickness of the wafer 100 measured by the thickness measuring unit 60. In this case, in the self-sharpening-decelerated grinding step, the second controller 9 grinds the wafer 100 with the grindstones 77 while supplying the second fluid and measuring the thickness of the wafer 100 with the thickness measuring unit 60. Then, the self-sharpening-decelerated grinding step transitions to the self-sharpening-accelerated grinding step, i.e., the control process carried out by the second controller 9 transitions to the control process carried out by the first controller 8, when the thickness value of the wafer 100 measured by the thickness measuring unit 60 has reached a preset second thickness threshold value.

Providing the self-sharpening-decelerated grinding step transitions to the self-sharpening-accelerated grinding step on the basis of the thickness of the wafer 100 measured by the thickness measuring unit 60, the thickness measuring unit 60 may measure the thickness of the wafer 100 while the self-sharpening-decelerated grinding step is suspended, i.e., temporarily interrupted.

In this case, in the self-sharpening-decelerated grinding step, the second controller 9 supplies the second fluid for decelerating the self-sharpening of the lower surfaces of the grindstones 77 and grinds the wafer 100 with the grindstones 77 until the lower surfaces of the grindstones 77 have further been moved, i.e., lowered, in the direction toward the wafer 100 by the predetermined distance after having contacted the wafer 100.

Thereafter, the second controller 9 carries out a thickness measuring step of stopping rotating the grindstones 77 and the chuck table 20 and measuring the thickness of the wafer 100 ground in the self-sharpening-decelerated grinding step with the thickness measuring unit 60. If the thickness measured in the thickness measuring step has not reached the second thickness threshold value, then the second controller 9 carries out a regrinding step of carrying out the self-sharpening-decelerated grinding step again. Specifically, the second controller 9 supplies the second fluid and grinds the wafer 100 with the grindstones 77 until the grindstones 77 are further moved in the direction toward the wafer 100, i.e., lowered, by a distance represented by the difference between the thickness measured in the thickness measuring step and the second thickness threshold value. Thereafter, the second controller 9 carries out the thickness measuring step again to confirm the thickness of the wafer 100, for example.

If the thickness measured in the thickness measuring step has reached the second thickness threshold value, then the self-sharpening-decelerated grinding step transitions to the self-sharpening-accelerated grinding step, i.e., the control process carried out by the second controller 9 transitions to the control process carried out by the first controller 8. In other words, the first controller 8 carries out the self-sharpening-accelerated grinding step of supplying the first fluid for promoting the self-sharpening of the lower surfaces of the grindstones 77 and grinding the wafer 100 to the preset thickness with the grindstones 77.

This process is effective when it is difficult to measure the thickness of the wafer 100 while the wafer 100 is being ground, as when the reverse side 102 of the wafer 100 has large surface irregularities. The second thickness threshold value is not limited to a particular thickness, but may represent a predetermined thickness range.

According to the present embodiment, the second controller 9 decides whether the load current value of the spindle motor 73 that rotates the grindstones 77 that are grinding the wafer 100 has reached the preset second current threshold value or not or the predetermined period of time has elapsed or not after the load current value of the spindle motor 73 reached the preset second current threshold value, whether the vertical loading value of the grindstones 77 has reached the preset second loading threshold value or not or the predetermined period of time has elapsed or not after the vertical loading value of the grindstones 77 reached the preset second loading threshold value, and whether the lower surfaces, i.e., the contact surfaces, of the grindstones 77 have further been moved, i.e., lowered, in the direction toward the wafer 100 by the predetermined distance or not after having contacted the wafer 100 in the self-sharpening-decelerated grinding step, while the wafer 100 is being ground at the second grinding speed V4 in the self-sharpening-decelerated grinding step. However, the second controller 9 may make the above decision at any desired timing in the self-sharpening-decelerated grinding step, rather than while the wafer 100 is being ground at the second grinding speed V4.

According to the first grinding process described above, the self-sharpening-accelerated grinding step is initially carried out, and after the self-sharpening-accelerated grinding step has transitioned to the self-sharpening-decelerated grinding step on the basis of the first current threshold value, the first loading threshold value, and/or the distance that the grindstones 77 have been lowered, the grindstones 77 grind the wafer 100 to the target thickness in the self-sharpening-decelerated grinding step. Alternatively, after the self-sharpening-accelerated grinding step has transitioned to the self-sharpening-decelerated grinding step, the self-sharpening-decelerated grinding step may transition to a second session of the self-sharpening-accelerated grinding step on the basis of the second current threshold value, the second loading threshold value, and/or the distance that the grindstones 77 have been lowered, and the grindstones 77 may grind the wafer 100 to the target thickness in the second session of the self-sharpening-accelerated grinding step. Furthermore, after the self-sharpening-decelerated grinding step has transitioned to the second session of the self-sharpening-accelerated grinding step, the second session of the self-sharpening-accelerated grinding step may transition to a second session of the self-sharpening-decelerated grinding step on the basis of the first current threshold value etc., and the grindstones 77 may grind the wafer 100 to the target thickness in the second session of the self-sharpening-decelerated grinding step.

Similarly, according to the second grinding process in which the self-sharpening-decelerated grinding step is initially carried out, after the self-sharpening-decelerated grinding step has transitioned to the self-sharpening-accelerated grinding step on the basis of the second current threshold value etc., the self-sharpening-accelerated grinding step may transition to a second session of the self-sharpening-decelerated grinding step on the basis of the first current threshold value etc., and the grindstones 77 may grind the wafer 100 to the target thickness in the second session of the self-sharpening-decelerated grinding step. Furthermore, after the second session of the self-sharpening-decelerated grinding step has been carried out, the second session of the self-sharpening-decelerated grinding step may transition to a second session of the self-sharpening-accelerated grinding step on the basis of the second current threshold value etc., and the grindstones 77 may grind the wafer 100 to the target thickness in the second session of the self-sharpening-accelerated grinding step.

According to the present embodiment, the first fluid used in the self-sharpening-accelerated grinding step is a liquid supplied at the preset first flow rate, and the second fluid used in the self-sharpening-decelerated grinding step is a liquid supplied at the second flow rate higher than the preset first flow rate. The first fluid may include a fluid for restraining the cooling of the grindstones 77 to promote the self-sharpening of the grindstones 77 compared to the second fluid.

For example, the first fluid may include air supplied at a preset third flow rate, and the second fluid may include a liquid supplied at a preset fourth flow rate. Specifically, in the self-sharpening-accelerated grinding step, the first controller 8 may control the first supply mechanism 80 to supply air at the third flow rate from the first air source 82 to the wafer 100 and the grindstones 77.

Air used as the first fluid is able to accelerate the self-sharpening of the grindstones 77 more than a liquid used as the first fluid. In this case, the third flow rate at which air is supplied as the first fluid is set to a range of 100 to 500 L/min., for example. The fourth flow rate at which the second fluid is supplied may be set to any flow rate capable of decelerating the self-sharpening of the grindstones 77.

The first fluid or the second fluid may be a mixed fluid, i.e., a two-fluid mixture of a liquid, e.g., water, and air, e.g., compressed air, that is supplied at a preset total flow rate as a fifth flow rate. Although the mixed fluid has a low cooling ability, it has a high capability of blowing off abrasive grains. The mixed fluid also has a cooling ability higher than air.

The mixed fluid that is supplied at the fifth flow rate representing the total flow rate may be used as the first fluid in the self-sharpening-accelerated grinding step, whereas the liquid that is supplied at the second flow rate may be used as the second fluid in the self-sharpening-decelerated grinding step. Alternatively, air that is supplied at the third flow rate may be used as the first fluid in the self-sharpening-accelerated grinding step, whereas the mixed fluid that is supplied at the fifth flow rate representing the total flow rate may be used as the second fluid in the self-sharpening-decelerated grinding step.

Both the first fluid and the second fluid may include a mixed fluid of a liquid and air. In this case, the first fluid may be supplied at the fifth flow rate representing the total flow rate, and the second fluid may be supplied at a sixth flow rate as a total flow rate higher than the fifth flow rate. In other words, the total flow rate of the first fluid represents the preset fifth flow rate, where the total flow rate of the second fluid represents the sixth flow rate higher than the fifth flow rate.

According to the present embodiment, the first controller 8 and the second controller 9 use the first supply mechanism 80 as a fluid supply mechanism in grinding the wafer 100. However, the first controller 8 and the second controller 9 may use the second supply mechanism 85 as a fluid supply mechanism instead of or in addition to the first supply mechanism 80 in grinding the wafer 100.

Specifically, the first fluid and the second fluid may be supplied from either one of or both the first supply mechanism 80 and the second supply mechanism 85. The first through sixth flow rates referred to above of the first fluid and the second fluid mean the total amounts or total flow rates of the first fluid and the second fluid supplied from the first supply mechanism 80 and the second supply mechanism 85.

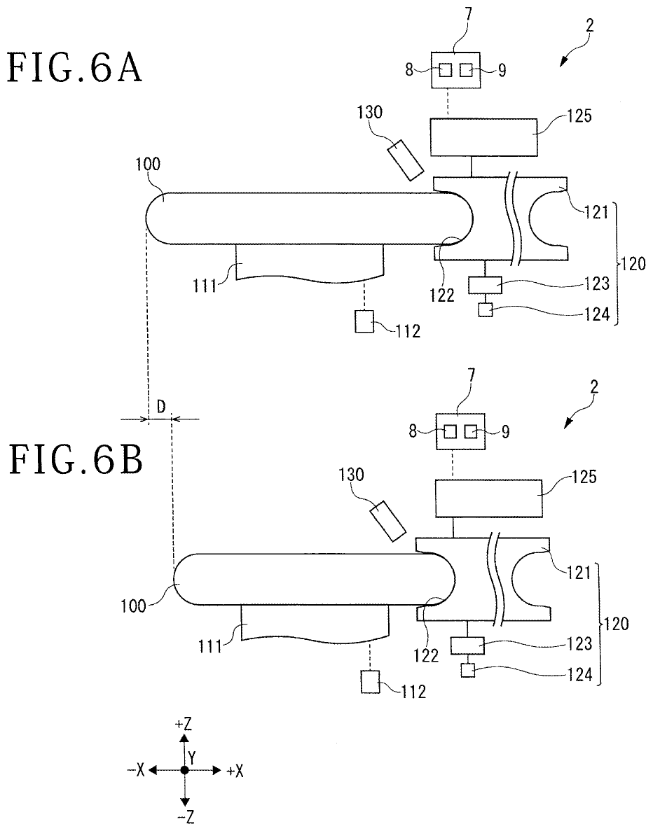

Furthermore, as illustrated in FIG. 1, the present embodiment is addressed to the grinding apparatus 1 for grinding the wafer 100 with the lower surfaces of the grindstones 77 arranged in the annular array. However, the grinding apparatus according to the present invention may include an edge grinding apparatus 2 illustrated in FIGS. 6A and 6B according to another embodiment of the present invention.

As illustrated in FIGS. 6A and 6B, the edge grinding apparatus 2 represents an example of a grinding apparatus for grinding the wafer 100 with a contact surface of a rotating beveling grindstone 121. In particular, the edge grinding apparatus 2 removes an edge or corner of an outer circumferential portion of the wafer 100 by an edge grinding process, i.e., a beveling process.

As illustrated in FIG. 6A, the edge grinding apparatus 2 includes a chuck table 111 for holding the wafer 100 thereon, the chuck table 111 being rotatable about the vertical central axis of the wafer 100, and an edge grinding mechanism 120 as an example of a grinding mechanism.

The edge grinding mechanism 120 includes the annular beveling grindstone 121 and an electric motor 123 for rotating the beveling grindstone 121 about its vertical central axis. The beveling grindstone 121 grinds off the edges of the wafer 100 when rotated about its vertical central axis by the electric motor 123. The edge grinding mechanism 120 also includes a load current value measuring unit 124. The load current value measuring unit 124 measures the load current value of the electric motor 123 that rotates the beveling grindstone 121 about its vertical central axis.

Moreover, the edge grinding apparatus 2 includes a moving mechanism 125 and a fluid supply mechanism 130. The moving mechanism 125 moves the chuck table 111 and the edge grinding mechanism 120, i.e., the beveling grindstone 121, relatively toward and away from each other in radial directions of the wafer 100 that extend perpendicularly to the vertical central axis of the beveling grindstone 121. The fluid supply mechanism 130 selectively supplies the first fluid and the second fluid, referred to above, at adjustable flow rates to the wafer 100 and the beveling grindstone 121.

Moreover, the edge grinding apparatus 2 includes a loading value measuring unit 112. The loading value measuring unit 112 measures a loading value applied relatively to the beveling grindstone 121 and the wafer 100, i.e., a loading value applied to press the grindstones 77 against the wafer 100 while the beveling grindstone 121 is grinding the wafer 100, when the moving mechanism 125 moves the chuck table 111 and the edge grinding mechanism 120, i.e., the beveling grindstone 121, relatively toward each other radially of the wafer 100. The loading value measuring unit 112 may be combined with the chuck table 111 or the edge grinding mechanism 120.

The edge grinding apparatus 2 also includes, as with the grinding apparatus 1 according to the above embodiment, the controller 7 that includes the first controller 8 and the second controller 9.

The edge grinding apparatus 2 configured as described above operates as follows. As illustrated in FIG. 6A, while the beveling grindstone 121 is in rotation, the contact surface of the beveling grindstone 121, i.e., a curved side surface 122 thereof, is brought into abrasive contact with the edge of the outer circumferential portion of the wafer 100 by the moving mechanism 125, and the beveling grindstone 121 is further moved in a direction toward the wafer 100, i.e., in the −X direction, by the moving mechanism 125. As illustrated in FIG. 6B, the edge of the outer circumferential portion of the wafer 100 is now ground off by a distance D, for example. The distance D is equivalent to the distance that the beveling grindstone 121 has been moved in the −X direction by the moving mechanism 125, i.e., the distance that the side surface 122 as the contact surface of the beveling grindstone 121 has been moved toward the wafer 100 after it abrasively contacted the edge of the outer circumferential portion of the wafer 100.

The controller 7 controls the edge grinding apparatus 2 to carry out the first grinding process and the second grinding process, referred to above, on the wafer 100.

According to the first grinding process, as illustrated in FIGS. 3 and 4, the self-sharpening-accelerated grinding step using the first fluid is initially carried out by the first controller 8, and the load current value, the loading value, and/or the distance that the beveling grindstone 121 has been moved is measured. When the load current value, the loading value, and/or the distance that the beveling grindstone 121 has reached the first current threshold value, the first loading threshold value, and/or the predetermined distance, the self-sharpening-accelerated grinding step transitions to the self-sharpening-decelerated grinding step using the second fluid that is controlled by the second controller 9. In the self-sharpening-decelerated grinding step, the beveling grindstone 121 grinds the wafer 100 to a preset diameter, for example.

According to the second grinding process, as illustrated in FIG. 5, the self-sharpening-decelerated grinding step using the second fluid is initially carried out by the second controller 9, and the load current value, the loading value, and/or the distance that the beveling grindstone 121 has been moved is measured. When the load current value, the loading value, and/or the distance that the beveling grindstone 121 has reached the second current threshold value, the second loading threshold value, and/or the predetermined distance, the self-sharpening-decelerated grinding step transitions to the self-sharpening-accelerated grinding step using the first fluid that is controlled by the first controller 8. In the self-sharpening-accelerated grinding step, the beveling grindstone 121 grinds the wafer 100 to a preset diameter, for example.

According to the present embodiment, the edge grinding apparatus 2 grinds the wafer 100 by switching between the self-sharpening-accelerated grinding step and the self-sharpening-decelerated grinding step. Therefore, compared to grinding the wafer 100 only in the self-sharpening-accelerated grinding step, abrasive grains dislodged from the beveling grindstone 121 are reduced, and the amount of wear of the beveling grindstone 121 is restrained. In addition, compared to grinding the wafer 100 only in the self-sharpening-decelerated grinding step, the fluids supplied to the beveling grindstone 121 are saved, the time required to grind the wafer 100 is shortened, and the processing quality of the wafer 100 is increased. According to the present embodiment, therefore, when the wafer 100 is ground, abrasive grains dropping off from the beveling grindstone 121 are minimized, and hence undue wear on the beveling grindstone 121 is restrained while at the same time maintaining a desired level of the processing quality of the ground surface of the wafer 100, resulting in a reduction in the frequency at which the beveling grindstone 121 is replaced.

According to the present invention, a grinding process including a self-sharpening-accelerated grinding step and a self-sharpening-decelerated grinding step is carried out in a processing cycle for grinding a wafer with grindstones by changing the flow rates of fluids supplied to the wafer on the basis of certain triggering events referred to in the description and claims. The grinding process thus performed can increase the processing quality of wafers successively ground, and reduces the amount of undue wear on the grindstones. Therefore, the grinding process is highly effective on the wafer ground in the processing cycle.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of grinding a wafer with contact surfaces of grindstones that are rotated, comprising:
a self-sharpening-accelerated grinding step of supplying a first fluid for accelerating self-sharpening of the contact surfaces of the grindstones to the wafer and the grindstones and grinding the wafer with the grindstones; and
a self-sharpening-decelerated grinding step of supplying a second fluid for decelerating self-sharpening of the contact surfaces of the grindstones to the wafer and the grindstones and grinding the wafer with the grindstones,
wherein, in the self-sharpening-accelerated grinding step when a load current value of a spindle motor that rotates the grindstones while the grindstones are grinding the wafer has reached a preset first current threshold value or a predetermined first period of time has elapsed after the load current value of the spindle motor reached the preset first current threshold value, or when a loading value for pressing the grindstones against the wafer has reached a preset first loading threshold value or a predetermined second period of time has elapsed after the loading value reached the preset first loading threshold value, or when the contact surfaces of the grindstones have further been moved in a direction toward the wafer by a predetermined distance after having contacted the wafer in the self-sharpening-accelerated grinding step, the self-sharpening-accelerated grinding step transitions to the self-sharpening-decelerated grinding step.

2. A method of grinding a wafer with contact surfaces of grindstones that are rotated, comprising:
a self-sharpening-accelerated grinding step of supplying a first fluid for accelerating self-sharpening of the contact surfaces of the grindstones to the wafer and the grindstones and grinding the wafer with the grindstones; and
a self-sharpening-decelerated grinding step of supplying a second fluid for decelerating self-sharpening of the contact surfaces of the grindstones to the wafer and the grindstones and grinding the wafer with the grindstones,
wherein, in the self-sharpening-accelerated grinding step when a load current value of a spindle motor that rotates the grindstones while the grindstones are grinding the wafer has reached a preset first current threshold value or a predetermined first period of time has elapsed after the load current value of the spindle motor reached the preset first current threshold value, and when a loading value for pressing the grindstones against the wafer has reached a preset first loading threshold value or a predetermined second period of time has elapsed after the loading value reached the preset first loading threshold value, the self-sharpening-accelerated grinding step transitions to the self-sharpening-decelerated grinding step.

3. A method of grinding a wafer with contact surfaces of grindstones that are rotated, comprising:
a self-sharpening-decelerated grinding step of supplying a second fluid for decelerating self-sharpening of the contact surfaces of the grindstones to the wafer and the grindstones and grinding the wafer with the grindstones; and
a self-sharpening-accelerated grinding step of supplying a first fluid for accelerating self-sharpening of the contact surfaces of the grindstones to the wafer and the grindstones and grinding the wafer with the grindstones,
wherein, in the self-sharpening-decelerated grinding step when a load current value of a spindle motor that rotates the grindstones while the grindstones are grinding the wafer has reached a preset second current threshold value or a predetermined first period of time has elapsed after the load current value of the spindle motor reached the preset second current threshold value, or when a loading value for pressing the grindstones against the wafer has reached a preset second loading threshold value or a predetermined second period of time has elapsed after the loading value reached the preset second loading threshold value, or when the contact surfaces of the grindstones have further been moved in a direction toward the wafer by a predetermined distance after having contacted the wafer in the self-sharpening-decelerated grinding step, the self-sharpening-decelerated grinding step transitions to the self-sharpening-accelerated grinding step.

4. A method of grinding a wafer with contact surfaces of grindstones that are rotated, comprising:
a self-sharpening-decelerated grinding step of supplying a second fluid for decelerating self-sharpening of the contact surfaces of the grindstones to the wafer and the grindstones and grinding the wafer with the grindstones; and
a self-sharpening-accelerated grinding step of supplying a first fluid for accelerating self-sharpening of the contact surfaces of the grindstones to the wafer and the grindstones and grinding the wafer with the grindstones,
wherein, in the self-sharpening-decelerated grinding step when a load current value of a spindle motor that rotates the grindstones while the grindstones are grinding the wafer has reached a preset second current threshold value or a predetermined first period of time has elapsed after the load current value of the spindle motor reached the preset second current threshold value, and when a loading value for pressing the grindstones against the wafer has reached a preset second loading threshold value or a predetermined second period of time has elapsed after the loading value reached the preset second loading threshold value, the self-sharpening-decelerated grinding step transitions to the self-sharpening-accelerated grinding step.

5. A method of grinding a wafer with contact surfaces of grindstones that are rotated, comprising:
a self-sharpening-accelerated grinding step of supplying a first fluid for accelerating self-sharpening of the contact surfaces of the grindstones to the wafer and the grindstones and grinding the wafer with the grindstones while measuring a thickness of the wafer with a thickness measuring unit; and
a self-sharpening-decelerated grinding step of supplying a second fluid for decelerating self-sharpening of the contact surfaces of the grindstones to the wafer and the grindstones and grinding the wafer to a preset thickness with the grindstones,
wherein, when the thickness of the wafer measured by the thickness measuring unit has reached a preset first thickness threshold value, the self-sharpening-accelerated grinding step transitions to the self-sharpening-decelerated grinding step.

6. A method of grinding a wafer with contact surfaces of grindstones that are rotated, comprising:
a self-sharpening-accelerated grinding step of supplying a first fluid for accelerating self-sharpening of the contact surfaces of the grindstones to the wafer and the grindstones and grinding the wafer with the grindstones until the contact surfaces of the grindstones have further been moved in a direction toward the wafer by a predetermined distance after having contacted the wafer;
a thickness measuring step of measuring a thickness of the wafer ground in the self-sharpening-decelerated grinding step; and
a self-sharpening-decelerated grinding step of supplying a second fluid for decelerating self-sharpening of the contact surfaces of the grindstones to the wafer and the grindstones and grinding the wafer to a preset thickness with the grindstones; and
a regrinding step of, when the thickness measured in the thickness measuring step has not reached a preset first thickness threshold value, supplying the first fluid to the wafer and the grindstones and grinding the wafer with the grindstones until the contact surfaces of the grindstones have further been moved in the direction toward the wafer by a distance represented by a difference between the thickness measured in the thickness measuring step and the first thickness threshold value,
wherein, when the thickness measured by the thickness measuring unit has reached the preset first thickness threshold value, the self-sharpening-accelerated grinding step transitions to the self-sharpening-decelerated grinding step.

7. A method of grinding a wafer with contact surfaces of grindstones that are rotated, comprising:
a self-sharpening-decelerated grinding step of supplying a second fluid for decelerating self-sharpening of the contact surfaces of the grindstones to the wafer and the grindstones and grinding the wafer with the grindstones while measuring a thickness of the wafer with a thickness measuring unit;
a thickness measuring step of measuring a thickness of the wafer ground in the self-sharpening-decelerated grinding step; and
a self-sharpening-accelerated grinding step of supplying a first fluid for accelerating self-sharpening of the contact surfaces of the grindstones to the wafer and the grindstones and grinding the wafer to a preset thickness with the grindstones,
wherein, when the thickness of the wafer measured by the thickness measuring unit has reached a preset second thickness threshold value, the self-sharpening-decelerated grinding step transitions to the self-sharpening-accelerated grinding step.

8. A method of grinding a wafer with contact surfaces of grindstones that are rotated, comprising:
a self-sharpening-decelerated grinding step of supplying a second fluid for decelerating self-sharpening of the contact surfaces of the grindstones to the wafer and the grindstones and grinding the wafer with the grindstones until the contact surfaces of the grindstones have further been moved in a direction toward the wafer by a predetermined distance after having contacted the wafer;
a thickness measuring step of measuring a thickness of the wafer ground in the self-sharpening-decelerated grinding step;
a self-sharpening-accelerated grinding step of supplying a first fluid for accelerating self-sharpening of the contact surfaces of the grindstones to the wafer and the grindstones and grinding the wafer to a preset thickness with the grindstones; and
a regrinding step of, when the thickness measured in the thickness measuring step has not reached a preset second thickness threshold value, supplying the second fluid to the wafer and the grindstones and grinding the wafer with the grindstones until the contact surfaces of the grindstones have further been moved in the direction toward the wafer by a distance represented by a difference between the thickness measured in the thickness measuring step and the second thickness threshold value,
wherein, when the thickness measured by the thickness measuring unit has reached the preset second thickness threshold value, the self-sharpening-decelerated grinding step transitions to the self-sharpening-accelerated grinding step.

9. The method of grinding a wafer according to claim 1, wherein the self-sharpening-accelerated grinding step transitions to the self-sharpening-decelerated grinding step when the load current value of the spindle motor that rotates the grindstones while the grindstones are grinding the wafer has become smaller than the preset first current threshold value or a third predetermined period of time has elapsed after the load current value of the spindle motor became smaller than the preset first current threshold value, or when the loading value for pressing the grindstones against the wafer has become smaller than the preset first loading threshold value or a fourth predetermined period of time has elapsed after the loading value became smaller than the preset first loading threshold value, or when the contact surfaces of the grindstones have further been moved in the direction toward the wafer by the predetermined distance after having contacted the wafer in the self-sharpening-accelerated grinding step.

10. The method of grinding a wafer according to claim 2, wherein the self-sharpening-accelerated grinding step transitions to the self-sharpening-decelerated grinding step when the load current value of the spindle motor that rotates the grindstones while the grindstones are grinding the wafer has become smaller than the preset first current threshold value or a third predetermined period of time has elapsed after the load current value of the spindle motor became smaller than the preset first current threshold value, and when the loading value for pressing the grindstones against the wafer has become smaller than the preset first loading threshold value or a fourth predetermined period of time has elapsed after the loading value became smaller than the preset first loading threshold value.

11. The method of grinding a wafer according to claim 3, wherein the self-sharpening-decelerated grinding step transitions to the self-sharpening-accelerated grinding step when the load current value of the spindle motor that rotates the grindstones while the grindstones are grinding the wafer has become larger than the preset second current threshold value or a third predetermined period of time has elapsed after the load current value of the spindle motor became larger than the preset second current threshold value, or when the loading value for pressing the grindstones against the wafer has become larger than the preset second loading threshold value or a fourth predetermined period of time has elapsed after the loading value became larger than the preset second loading threshold value, or when the contact surfaces of the grindstones have further been moved in the direction toward the wafer by the predetermined distance after having contacted the wafer in the self-sharpening-decelerated grinding step.

12. The method of grinding a wafer according to claim 4, wherein the self-sharpening-decelerated grinding step transitions to the self-sharpening-accelerated grinding step when the load current value of the spindle motor that rotates the grindstones while the grindstones are grinding the wafer has become larger than the preset second current threshold value or a third predetermined period of time has elapsed after the load current value of the spindle motor became larger than the preset second current threshold value, and when the loading value for pressing the grindstones against the wafer has become larger than the preset second loading threshold value or a fourth predetermined period of time has elapsed after the loading value became larger than the preset second loading threshold value.

13. The method of grinding a wafer according to claim 1,
wherein the first fluid includes a liquid supplied at a preset first flow rate, and
the second fluid includes a liquid supplied at a second flow rate higher than the preset first flow rate.

14. The method of grinding a wafer according to claim 1,
wherein the first fluid includes air supplied at a preset third flow rate, and
the second fluid includes a liquid supplied at a preset fourth flow rate.

15. The method of grinding a wafer according to claim 1, wherein the first fluid or the second fluid includes a mixture of a liquid and air.

16. The method of grinding a wafer according to claim 1,
wherein the first fluid and the second fluid include a mixture of a liquid and air, and
the first fluid is supplied at a total flow rate as a fifth flow rate, and the second fluid is supplied at a total flow rate as a sixth flow rate higher than the fifth flow rate.

17. An apparatus for grinding a wafer with contact surfaces of grindstones that are rotated, comprising:
a chuck table for holding the wafer thereon;
a grinding mechanism for grinding the wafer on the chuck table, the grinding mechanism having the grindstones and an electric motor for rotating the grindstones that are arranged in an annular array about a central axis of the annular array;
a moving mechanism for moving the chuck table and the grinding mechanism relatively toward and away from each other;
a fluid supply mechanism for selectively supplying a first fluid and a second fluid at adjustable flow rates to the wafer and the grindstones;
a load current value measuring unit for measuring a load current value of the electric motor when the electric motor rotates the grindstones; and
a controller,
wherein the controller includes
a first controller for carrying out a control process to control the fluid supply mechanism to supply the first fluid and move the chuck table and the grindstones relatively in directions toward each other at a predetermined feed speed, thereby grinding the wafer with the grindstones, and
a second controller for carrying out a control process to control the fluid supply mechanism to supply the second fluid and move the chuck table and the grindstones relatively in directions toward each other at a predetermined feed speed, thereby grinding the wafer with the grindstones,
the control process carried out by the first controller transitions to the control process carried out by the second controller when the load current value has reached a preset first current threshold value or a predetermined first period of time has elapsed after the load current value reached the preset first current threshold value, and
the control process carried out by the second controller transitions to the control process carried out by the first controller when the load current value has reached a preset second current threshold value or a predetermined second period of time has elapsed after the load current value reached the preset second current threshold value.

18. The apparatus for grinding a wafer according to claim 17, further comprising:
a loading value measuring unit for measuring a loading value applied relatively to the grindstones and the wafer,
wherein the control process carried out by the first controller transitions to the control process carried out by the second controller when the loading value has reached a preset first loading threshold value or a third predetermined period of time has elapsed after the loading value has reached the preset first loading threshold value, and
the control process carried out by the second controller transitions to the control process carried out by the first controller when the loading value has reached a preset second loading threshold value or a fourth predetermined period of time has elapsed after the loading value has reached the preset second loading threshold value.

19. An apparatus for grinding a wafer with contact surfaces of grindstones that are rotated, comprising:
a chuck table for holding the wafer thereon;
a grinding mechanism for grinding the wafer on the chuck table, the grinding mechanism having the grindstones and an electric motor for rotating the grindstones that are arranged in an annular array about a central axis of the annular array;
a moving mechanism for moving the chuck table and the grinding mechanism relatively toward and away from each other;
a fluid supply mechanism for selectively supplying a first fluid and a second fluid at adjustable flow rates to the wafer and the grindstones, and
a controller,
wherein the controller includes
a first controller for carrying out a control process to control the fluid supply mechanism to supply the first fluid and move the chuck table and the grindstones relatively in directions toward each other at a predetermined first feed speed, thereby grinding the wafer with the grindstones, and
a second controller for carrying out a control process to control the fluid supply mechanism to supply the second fluid and move the chuck table and the grindstones relatively in directions toward each other at a predetermined second feed speed, thereby grinding the wafer with the grindstones, and
the control process carried out by the first controller transitions to the control process carried out by the second controller or the control process carried out by the second controller transitions to the control process carried out by the first controller when the contact surfaces of the grindstones have further been moved in a direction toward the wafer by a predetermined distance after having contacted the wafer.

20. An apparatus for grinding a wafer with contact surfaces of grindstones that are rotated, comprising:
a chuck table for holding the wafer thereon;
a grinding mechanism for grinding the wafer on the chuck table, the grinding mechanism having the grindstones and an electric motor for rotating the grindstones that are arranged in an annular array about a central axis of the annular array;
a moving mechanism for moving the chuck table and the grinding mechanism relatively toward and away from each other;
a fluid supply mechanism for selectively supplying a first fluid and a second fluid at adjustable flow rates to the wafer and the grindstones;
a load current value measuring unit for measuring a load current value of the electric motor when the electric motor rotates the grindstones;
a loading value measuring unit for measuring a loading value applied relatively to the grindstones and the wafer; and
a controller,
wherein the controller includes
a first controller for carrying out a control process to control the fluid supply mechanism to supply the first fluid and move the chuck table and the grindstones relatively in directions toward each other at a predetermined first feed speed, thereby grinding the wafer with the grindstones, and
a second controller for carrying out a control process to control the fluid supply mechanism to supply the second fluid and move the chuck table and the grindstones relatively in directions toward each other at a predetermined second feed speed, thereby grinding the wafer with the grindstones,
the control process carried out by the first controller transitions to the control process carried out by the second controller when the load current value has reached a preset first current threshold value or a predetermined first period of time has elapsed after the load current value reached the preset first current threshold value, and when the loading value has reached a preset first loading threshold value or a predetermined second period of time has elapsed after the loading value reached the preset first loading threshold value, and
the control process carried out by the second controller transitions to the control process carried out by the first controller when the load current value has reached a preset second current threshold value or a predetermined third period of time has elapsed after the load current value reached the preset second current threshold value, and when the loading value has reached a preset second loading threshold value or a predetermined fourth period of time has elapsed after the loading value reached the preset second loading threshold value.

21. The apparatus for grinding a wafer according to claim 17, further comprising:
a thickness measuring unit for measuring a thickness of the wafer held on the chuck table,
wherein the control process carried out by the first controller also transitions to the control process carried out by the second controller when the thickness of the wafer measured by the thickness measuring unit has reached a preset first thickness threshold value, and
the control process carried out by the second controller also transitions to the control process carried out by the first controller when the thickness of the wafer measured by the thickness measuring unit has reached a preset second thickness threshold value.
